(19) United States
(12) Patent Application Publication
(10) Pub. No.: US 2012/0099363 A1
(43) Pub. Date: Apr. 26, 2012

(54) RESISTANCE CHANGE TYPE MEMORY

(75) Inventor: Satoshi Inaba, Yokohama-shi (JP)

(73) Assignee: KABUSHIKI KAISHA TOSHIBA, Tokyo (JP)

(21) Appl. No.: 13/235,638

(22) Filed: Sep. 19, 2011

(30) Foreign Application Priority Data
Oct. 21, 2010 (JP) 2010-236448

(51) Int. Cl. G11C 11/21

(52) U.S. Cl. 365/148

(57) ABSTRACT

According to one embodiment, a resistance change type memory includes a first bit line extending in a first direction, a first word line extending in a second direction, a first bipolar transistor which is a first drive type and has a first emitter, a first base, and a first collector, a second bipolar transistor which is a second drive type different from the first drive type and has a second emitter, a second base, and a second collector, and a first memory element which has first and second terminals and in which a change in resistance state thereof is associated with data. The first terminal is connected to the first and second emitters, the second terminal is connected to the first bit line, and the first and second bases are connected to the first word line.

### CROSS-REFERENCE TO RELATED APPLICATIONS

This application is based upon and claims the benefit of priority from prior Japanese Patent Application No. 2010-236448, filed Oct. 21, 2010, the entire contents of which are incorporated herein by reference.

### FIELD

Embodiments described herein relate generally to a resistance change type memory.

### BACKGROUND

In recent years, much attention has been paid to a resistance change type memory such as an MRAM (Magnetoresistive RAM), an ReRAM (Resistive RAM), or a PC RAM (Phase Change RAM) that associates a change in characteristics of a memory element with data to be stored as a new memory device.

Each memory cell in the resistance change type memory includes, e.g., a resistance change type memory element and a field-effect transistor as a selecting switch.

To increase the storage density, miniaturization of the memory cell has been advanced, and sizes of the memory element and the field-effect transistor are reduced. However, long channel characteristics of the field-effect transistor may be possibly deteriorated due to a reduction in size of the field-effect transistor. As a result, characteristics of the resistance change type memory may be possibly deteriorated.

### BRIEF DESCRIPTION OF THE DRAWINGS

FIG. 1A is an equivalent circuit schematic showing a configuration of a memory cell of a resistance change type memory according to an embodiment;

FIGS. 1B and 1C are views each showing a configuration of a memory element;

FIGS. 2A, 2B, 3A, 3B, 4A, 4B, 5A and 5B are views for explaining an operation of the memory cell in the resistance change type memory according to the embodiment;

FIGS. 6A, 6B, 7A, and 7B are views each showing a structural example of the memory cell in the resistance change type memory according to the embodiment;

FIG. 8 is an equivalent circuit schematic showing a configuration of a memory cell array in the resistance change type memory according to the embodiment;

FIGS. 9A, 9B, 10A, 10B, 11A, and 11B are views for explaining an operation of the resistance change type memory according to the embodiment;

FIGS. 12, 13, 14A, and 14B are views each showing a structural example of the memory cell or memory cell array in the resistance change type memory according to the embodiment;

FIGS. 15A, 15B, 16A, and 16B are views each showing a step in a manufacturing method of a resistance change type memory according to the embodiment;

FIGS. 17, 18, 19A, and 19B are views each showing a structural example of the memory cell in the resistance change type memory according to the embodiment;

FIGS. 20A, 20B, 20C, 21A, 21B, 22A, and 22B are views each showing a step in a manufacturing method of a resistance change memory according to the embodiment; and

FIG. 23 is a view showing a modification of the resistance change type memory according to the embodiment.

### DETAILED DESCRIPTION

### Embodiment

An embodiment will now be described hereinafter with reference to the accompanying drawings. In the following description, like reference numerals denote elements having the same functions and configurations, and an overlapping explanation will be given as required.

In general, according to one embodiment, a resistance change type memory includes a first bit line extending in a first direction; a first word line extending in a second direction; a first bipolar transistor which is a first drive type and has a first emitter, a first base, and a first collector; a second bipolar transistor which is a second drive type different from the first drive type and has a second emitter, a second base, and a second collector; and a first memory element which has first and second terminals and in which a change in resistance state thereof is associated with data. The first terminal is connected to the first and second emitters, the second terminal is connected to the first bit line, and the first and second bases are connected to the first word line.

### (1) Basic Example

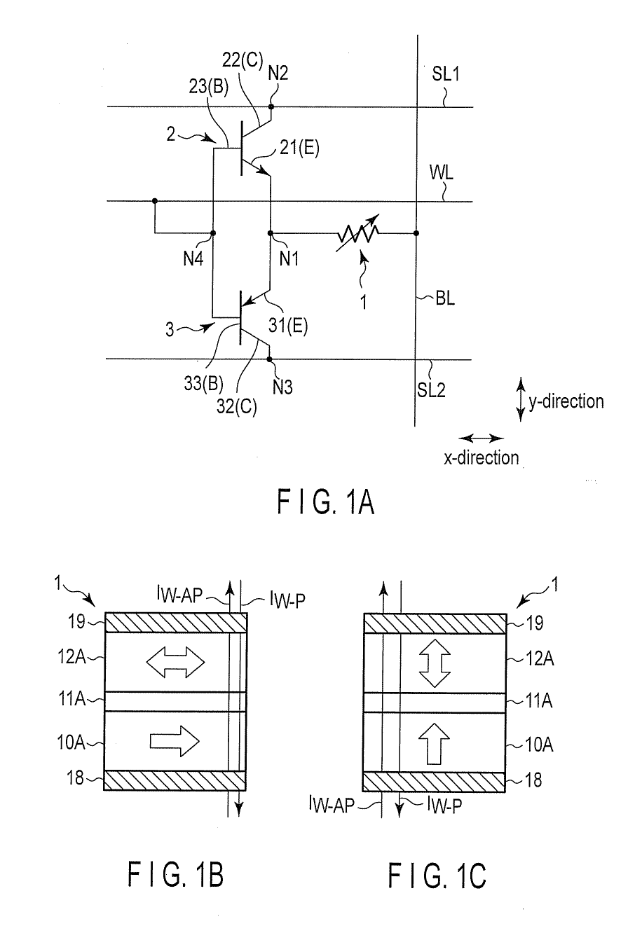

A memory cell in a resistance change type memory will be described as a basic example of a resistance change type memory device according to this embodiment with reference to FIGS. 1A to 7B.

### (a) Circuit Configuration

A circuit configuration of a memory cell in the resistance change type memory device according to this embodiment will now be described with reference to FIGS. 1A, 1B, and 1C.

FIG. 1A is an equivalent circuit schematic of a memory cell MC in a resistance change type memory device according to this embodiment.

As shown in FIG. 1A, the memory cell MC in the resistance change type memory device according to this embodiment includes one resistance change type memory element 1 and two bipolar transistors (BJT: Bipolar Junction Transistors).

In this embodiment, an MRAM (Magnetoresistive RAM) or an STT-RAM (Spin Transfer Torque RAM) is exemplified as the resistance change type memory.

In the MRAM, the resistance change type memory element 1 is, e.g., a magnetoresistive element (magnetoresistive effect element).

Each of FIGS. 1B and 1C shows a configuration of the magnetoresistive element. The magnetoresistive element used for the memory element 1 is an MTJ (Magnetic Tunnel Junction) element.

The MTJ element 1 has a first magnetic layer 10A having an invariable (fixed) direction of magnetization, a second magnetic layer 12A having a variable direction of magnetization, and a non-magnetic layer 11A between the two magnetic layers 10A and 12A. The two magnetic layers 10A and 12A and the non-magnetic layer 11A form a magnetic tunnel junction. This magnetic tunnel junction is provided between two electrodes 18 and 19.

In this embodiment, the magnetic layer 10A having the invariable direction of magnetization is called a reference layer 10A, and the magnetic layer 12A having the variable direction of magnetization is called a recording layer 12A. The reference layer 10A is also called a magnetization invariable layer, a pin layer, or a pinned layer, and the recording layer 12A is also called a magnetization free layer and a free layer.

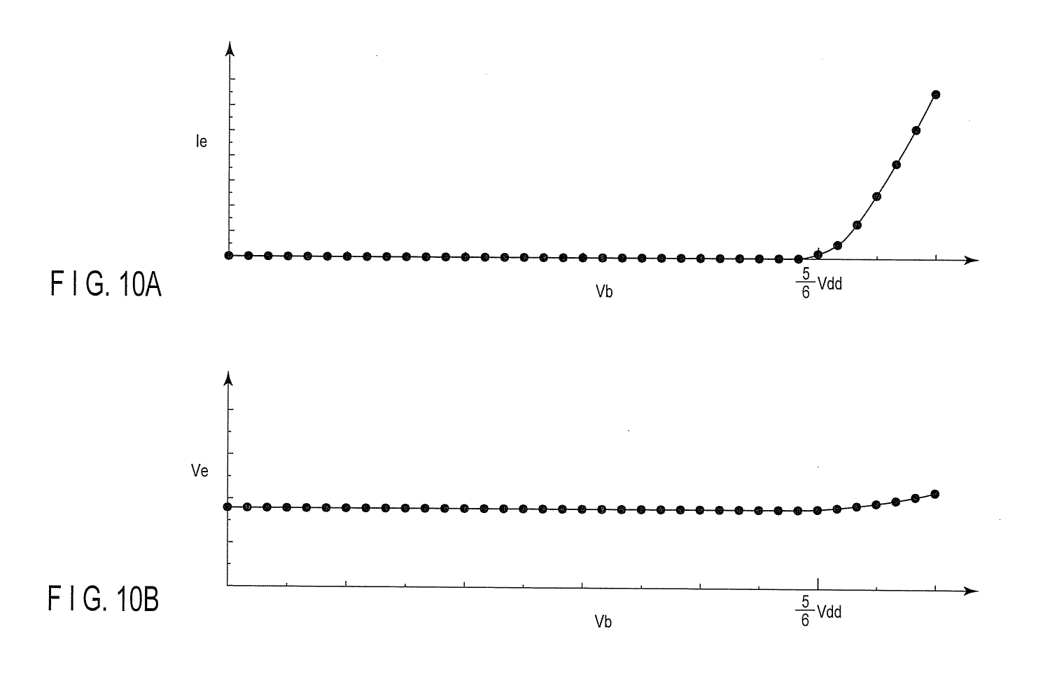

FIG. 1B shows an in-plane magnetization type MTJ element 1. FIG. 10 shows a perpendicular magnetization type MTJ element 1. In the in-plane magnetization type MTJ element 1, directions of magnetization in the magnetic layers 10A and 12A are parallel to a film surface. In the perpendicular magnetization type MTJ element 1, directions of magnetization in the magnetic layers 10B and 12B are perpendicular to a film surface.

The direction of magnetization in the recording layer 12A changes by a spin transfer magnetization switching system. That is, the direction of magnetization in the recording layer 12A changes when spin-polarized electrons included in currents I_{W-AP} and I_{W-P} flowing through the element 1 function with respect to magnetization (spin) of the recording layer 12A.

A phrase “the direction of magnetization in the reference layer 10A is invariable” or “the direction of magnetization in the reference layer 10A is fixed” means that the direction of magnetization in the reference layer 10A does not change when an STT switching current (a threshold current for switching of magnetization) used for switching of the magnetizing direction of the recording layer 12A is flowed through the reference layer 10A. Therefore, in the MTJ element 1, a magnetic layer having a large threshold current for switching of magnetization is used as the reference layer 10A, and a magnetic layer having a smaller reference threshold current than that of the reference layer 10A is used as the recording layer 12A. As a result, the MTJ element 1 including the recording layer 12A having the variable direction of magnetization and the reference layer 10A having the invariable direction of magnetization is formed.

When changing the direction of magnetization in the recording layer 12A and the direction of magnetization in the reference layer 10A from an anti-parallel state to a parallel state by the spin transfer magnetization switching system, i.e., when equalizing the direction of magnetization in the recording layer 12A and the direction of magnetization in the reference layer 10A, the current I_{W-P} flowing from the recording layer 12A toward the reference layer 10A is supplied to the MTJ element 1. In this case, electrons move from the reference layer 10A toward the recording layer 12A through the tunnel barrier layer 11A. A majority of the electrons (spin-polarized electrons) that have passed through the reference layer 10A and the tunnel barrier layer 11A have the same direction as the direction of magnetization (spin) of the reference layer 10A. A spin angular momentum (spin torque) of the spin-polarized electrons is applied to the magnetization of the recording layer 10A, thereby reversing the direction of magnetization in the recording layer 12A. When the magnetization arrangement of the two magnetic layers 10A and 12A is a parallel arrangement, the MTJ element 1 has the smallest resistance value. For example, data “0” is assigned to the MTJ element 1 in which the magnetization arrangement is the parallel arrangement.

When changing the direction of magnetization in the recording layer 12A and the direction of magnetization in the reference layer 10A from the parallel state to the anti-parallel state, i.e., when setting the direction of magnetization in the recording layer 12A to be opposite to the direction of magnetization in the reference layer 10A, the current I_{W-AP} flowing from the reference layer 10A to the recording layer 12A is supplied to the MTJ element. In this case, the electrons move from the recording layer 12A toward the reference layer 10A. The electrons having the spin which is anti-parallel to the direction of magnetization in the reference layer 10A are reflected by the reference layer 10A. The reflected electrons are injected into the recording layer 12A as spin-polarized electrons. The spin angular momentum of the spin-polarized electrons (the reflected electrons) is applied to the magnetization of the recording layer 12A, and the direction of magnetization in the recording layer 12A is changed to be opposite (anti-parallel arrangement) to the direction of magnetization of the reference layer 10A. When the magnetization arrangement of the two magnetic layers 10A and 12A is the anti-parallel arrangement, the MTJ element 1 has the largest resistance value. For example, data “1” is assigned to the MTJ element 1 in which the magnetization arrangement is the anti-parallel arrangement.

The bipolar transistors 2 and 3 in the memory cell MC are used as switching devices configured to supply a current to the MTJ element 1.

One bipolar transistor 2 of the two bipolar transistors 2 and 3 in the memory cell MC is an NPN-type (a first drive type) bipolar transistor 2, and the other bipolar transistor 3 is a PNP-type (a second drive type) bipolar transistor 3.

To the memory cell MC are connected one word line WL, one bit line BL, and two power supply lines SL1 and SL2.

A connection relationship between the respective devices 1, 2, and 3 in the memory cell MC and the respective interconnects WL, BL, SL1, and SL2 is as follows.

An emitter 21(E) of the NPN-type bipolar transistor 2 is connected to an emitter 31(E) of the PNP-type bipolar transistor 3. The emitter 21 and the emitter 31 connected to each other form a connection node N1. The connection node N1 will be also referred to as a common emitter hereinafter.

A connector 22(C) of the NPN-type bipolar transistor 2 is connected to the power supply line SL1. A collector 32(C) of the PNP-type bipolar transistor 3 is connected to the power supply line SL2. A connection node N2 is formed between the collector 22 of the NPN-type bipolar transistor 2 and the power supply line SL1, and a connection node N3 is formed between the collector 32 of the PNP-type bipolar transistor and the power supply line SL2.

A base 23(B) of the NPN-type bipolar transistor 2 is connected to a base 33(B) of the PNP-type bipolar transistor 3. The bases 23 and 33 connected to each other form a connection node N4. The connection node N4 will be also referred to as a common base hereinafter.

The bit line BL extends in, e.g., y-direction (a first direction). The word line WL extends in x-direction (a second direction) crossing the y-direction.

The two power supply lines SL1 and SL2 extend in, e.g., the x-direction. However, the extending direction of the power supply lines SL1 and SL2 may be the y-direction. The power supply line SL1 is connected to a high-potential end (a power supply Vdd), and the power supply line SL2 is connected to a low-potential end (a ground end). A potential (a voltage) of the power supply line SL1 is set to a power supply potential Vdd, and a potential of the power supply line SL2 is set to a ground potential Vss. The power supply line SL2 set to the ground potential will be referred to as a ground line SL2 hereinafter.

One end (an electrode) of the MTJ element 1 as the resistance change type memory element is connected to the connection node (the common emitter) N1 of the two bipolar transistors 2 and 3. The other end of the MTJ element 1 is connected to the bit line BL. The emitters 21 and 31 of the bipolar transistors 2 and 3 are connected to the bit line BL through the MTJ element 1.

The word line WL is connected to the connection node (the common base) N4 of the two bipolar transistors 2 and 3. The bases 23 and 33 of the NPN-type and PNP-type bipolar transistors 2 and 3 are connected to the word line WL.

In the resistance change type memory device according to this embodiment, controlling a potential of the bit line BL connected to the emitters 21 and 31 of the two bipolar transistors 2 and 3 and a potential of the word line WL connected to the bases 23 and 33 of the bipolar transistors 2 and 3 enables the write currents I_{W-P} and I_{W-AP} used for changing a resistance state of the resistance change type memory element (e.g., the MTJ element) 1 to bi-directionally flow through this element 1.

By controlling of the potentials in the bit line BL and the word line WL, one bipolar transistor is turned on, and the other bipolar transistor is turned off. For example, when the PNP-type bipolar transistor 3 is turned on, a current flowing from the bit line BL side to the connection node N1 side is supplied to the MTJ element 1. When the NPN-type bipolar transistor 2 is turned on, a current flowing from the connection node N1 side to the bit line BL side is supplied to the MTJ element 1.

When the field-effect transistor is used in a memory cell, an output current from the field-effect transistor is decreased as a size of the field-effect transistor is reduced based on miniaturization of the memory cell. As a result, a margin for a threshold current that changes a resistance state of the MTJ element may not be possibly assured.

When the bipolar transistors 2 and 3 are provided in place of the field-effect transistor in the memory cell like this embodiment, an output current from each of the bipolar transistors 2 and 3 is set in accordance with a potential difference between terminals of the bipolar transistors 2 and 3 or impurity concentration in each semiconductor layer to form the bipolar transistors 2 and 3. Therefore, when the potential difference or the impurity concentration is appropriately set, each of the bipolar transistors 2 and 3 can output a write current higher than a switching threshold current of the MTJ element 1, whereby the write current having a margin assured for the switching threshold current of the MTJ element 1 can be supplied to the MTJ element 1 in the memory cell.

Considering a variation in characteristics (the switching threshold current) of the MTJ element when the memory cells MC form a memory cell array, it is effective to assure a margin for an upper limit value/lower limit value of the write current based on the output current from each of the bipolar transistors 2 and 3 like this embodiment. Therefore, the reliability of operations of the memory can be improved in this embodiment.

Further, deterioration of electrical characteristics of the bipolar transistor brought about by the miniaturization of the memory cell, such as a short channel effect of the field-effect transistor, hardly appears as compared with the field-effect transistor. Therefore, in this embodiment, when the bipolar transistor is used as a device that controls supply of a current to the resistance change type memory element 1 in place of the field-effect transistor, an adverse effect caused due to the miniaturization of the memory cell can be reduced.

### (b) Operation

An operation of the resistance change type memory (e.g., an MRAM) according to this embodiment will now be described with reference to FIGS. 1A to 5B.

(b-1) Write Operation

Writing data in the resistance change type memory element (the MTJ element) in the memory cell MC will now be described with reference to FIGS. 1A, 1B, 1C, 2A, 2B, 3A, 3B, 4A, and 4B.

Here, description will be given as to an example that the recording layer 12A of the MTJ element 1 is arranged on the bit line BL side and the reference layer 10A of the MTJ element 1 is arranged on the connection node (the common emitter) N1 side.

As described above, when writing data into the MTJ element 1 by the spin transfer magnetization switching system, the write current must be bi-directionally flown through the MTJ element 1 in accordance with the data that is to be written into the MTJ element 1.

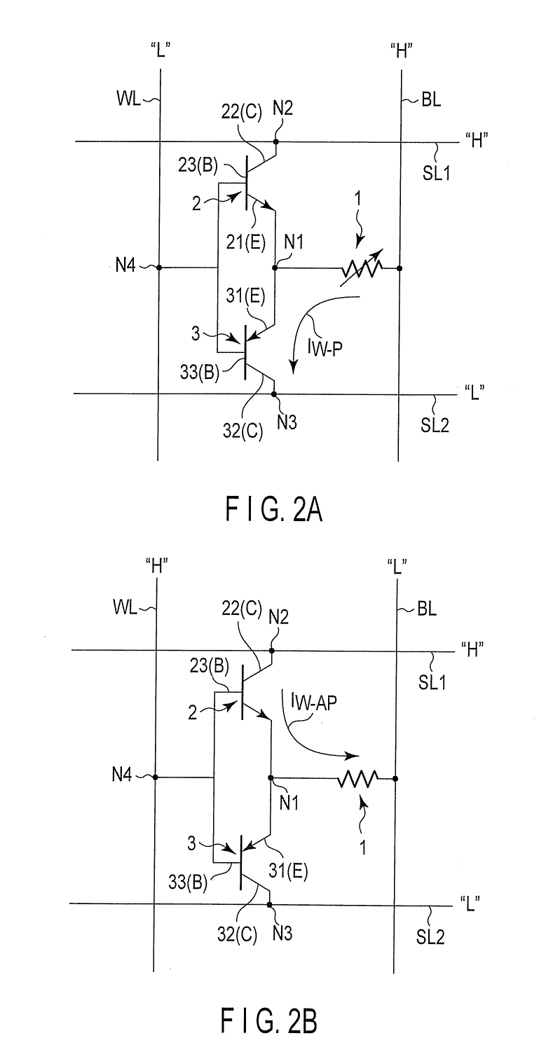

An example of changing the magnetization arrangement of the MTJ element 1 from the anti-parallel state (AP state) to the parallel state (P state) will be first explained with reference to FIG. 2A.

When changing the magnetization arrangement of the two magnetic layers (the reference layer/the recording layer) 10A and 12A in the MTJ element 1 from AP state to P state, electrons are injected into the recording layer 12A from the reference layer 10A. That is, the write current I_{W-P} required to change the magnetization arrangement to the parallel state is flowed from the recording layer 12A to the reference layer 10A in the opposite direction of a moving direction of the electrons.

In this case, since the write current I_{W-P} is a current that flows from the bit line BL side toward the connection node N1, the NPN bipolar transistor 2 is turned off, and the PNP-type bipolar transistor 3 is turned on.

To turn on/off the bipolar transistors 2 and 3, the potentials in the bit line BL and the word line WL are controlled.

The potential in the word line WL corresponds to the base voltage Vb of each of the transistors 2 and 3. When turning off the NPN-type bipolar transistor 2 and turning on the PNP-type bipolar transistor 3, the base voltage (the potential in the node N4) of each of the bipolar transistors 2 and 3 is adjusted to be smaller than the emitter voltage (the potential in the node N1) of each of the bipolar transistors 2 and 3. That is, the potential in the word line WL is adjusted to be lower than the potential in the bit line BL.

In the NPN-type bipolar transistor 2, when the base voltage Vb is lower than the emitter voltage Ve, the voltage Veb between the emitter (E) and the base (B) in the NPN-type bipolar transistor 2 becomes a positive voltage. Therefore, a reverse bias is applied to a PN junction associated with the emitter-base of the NPN-type bipolar transistor 2, and the NPN-type bipolar transistor 2 is turned off.

Therefore, when changing the magnetization arrangement of the MTJ element 1 from AP state to P state, it is sufficient to consider operations of the MTJ element 1 and the PNP-type bipolar transistor 3 under conditions that the potential in the word line WL as the base potential Vb is smaller than the potential in the node N1 as the emitter voltage Ve (i.e., Vb<Ve).

The emitter voltage Ve corresponds to a voltage that is applied from the bit line BL through the MTJ element 1. Therefore, an application voltage (e.g., the voltage Vdd) for the bit line BL drops due to a resistance value of the MTJ element 1, and hence the emitter voltage Ve becomes smaller than the voltage Vdd. Furthermore, since the emitter voltage Ve is dependent on an amount of a current flowing through the connection node (the common emitter) N1, the emitter voltage Ve is modulated by the base voltage Vb.

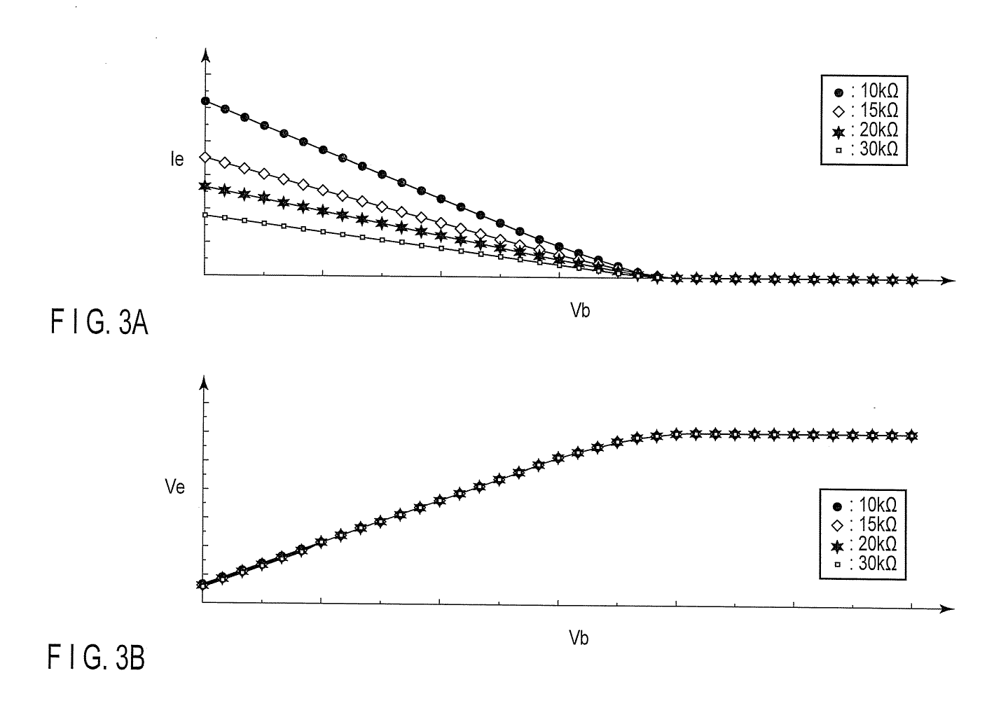

Description will now be given as to a relationship between the base voltage Vb and the emitter voltage Ve and a relationship between the base voltage Vb and an emitter current Ie in the PNP-type bipolar transistor 3 in FIG. 2A with references to FIGS. 3A and 3B.

Each of FIGS. 3A and 3B shows a simulation result concerning a circuit of the PNP-type bipolar transistor 3 and the MTJ element in the memory cell MC. In the simulation of each of FIGS. 3A and 3B (SPICE simulation in this example), a resistance value of the MTJ element 1 is set to one of several parameter values, and an operation model of the bipolar transistor is set as an appropriate model. It is to be noted that the emitter voltage Ve and the emitter current Ie when the base voltage Vb is swept are shown in the simulation of FIGS. 3A and 3B.

A collector voltage Vc of the PNP-type bipolar transistor 3 is set to 0 V, and the base voltage Vb is changed from 0 V to the power supply voltage Vdd (approximately 1.0 V to 2.0 V). The potential in the bit line BL is set to the voltage Vdd. The resistance value of the MTJ element 1 is changed as each parameter. As the resistance values of the MTJ element 1, 10 kΩ, 15 kΩ, 20 kΩ, and 30 kΩ are assumed, respectively.

FIG. 3A shows a relationship between the base voltage Vb and the emitter current Ie in the PNP-type bipolar transistor 3. In FIG. 3A, an abscissa of a graph is associated with the base voltage Vb, and an ordinate of the graph is associated with the emitter current Ie.

FIG. 3B shows a relationship between the base voltage Vb and the emitter voltage Ve in the PNP-type bipolar transistor 3. In FIG. 3B, an abscissa of a graph is associated with the base voltage Vb, and an ordinate of the graph is associated with the emitter voltage Ve.

As shown in FIG. 3A, in regard to each resistance value of the MTJ element, when the base voltage Vb of the PNP-type bipolar transistor 3 is set to 0 V, the emitter current Ie has a maximum value. When the base voltage Vb becomes close to the voltage Vdd of the bit line, the emitter current Ie has a minimum value.

When the resistance value of the MTJ element 1 increases, an absolute value of the emitter current Ie in the PNP-type bipolar transistor 3 is reduced.

Moreover, as shown in FIG. 3B, when the emitter current Ie flows, the emitter voltage Ve in the PNP-type bipolar transistor 3 increases. An intensity of the emitter voltage Ve changes with substantially the same intensity without being dependent on the resistance value of the MTJ element 1.

As represented by the simulation result in each of FIGS. 3A and 3B, when the base voltage is 0 V, a base-emitter voltage Vbe has a maximum value, and the emitter current Ie has a maximum value.

Therefore, when changing the magnetization arrangement of the MTJ element from AP state to P state, the potential in the word line WL is adjusted to approximately 0 V with respect to the potential in the bit line BL having the power supply voltage Vdd (e.g., approximately 1.0 V to 2.0 V). As a result, the efficiency for writing data by using the output current from the PNP-type bipolar transistor 3 can be improved.

An example of changing the magnetization arrangement of the MTJ element 1 from the parallel state (P state) to the anti-parallel state (AP state) will now be described with reference to FIG. 2B. An operation in this example is opposite to the operation in the example of changing to P state from AP state.

When changing the magnetization arrangement of the MTJ element 1 from P state to AP state, electrons are injected from the recording layer 12A to the reference layer 10A. That is, the write current I_{W-AP} required for changing the magnetization arrangement to AP state is flowed from the reference layer 10A to the recording layer 12A.

As shown in FIG. 2B, in a write operation from P state to AP state, the write current I_{W-AP} flowing in the opposite direction of the current I_{W-P} shown in FIG. 2A is flowed through the MTJ element 1 by using the NPN-type bipolar transistor 2.

The write current I_{W-AP} is a current flowing from the connection node N1 side toward the bit line BL side. Therefore, in the case of this operation, the NPN-type bipolar transistor 2 is turned on, and the PNP-type bipolar transistor 3 is turned off.

The potential in the bit line BL is set to an “L” level (0 V), and the potential in the power supply line SL1 is set to an “H” level (Vdd). As a result, the current I_{W-AP} is flowed from the power supply line SL1 toward the bit line BL.

The base voltage Vb of each of the bipolar transistors 2 and 3, i.e., the potential in the word line WL is set in such a manner that the NPN-type bipolar transistor 2 alone is turned on and the PNP-type bipolar transistor 3 is turned off.

When the base voltage Vb (the potential in the word line WL) is higher than the emitter voltage (the potential in the node N1) Ve in the PNP-type bipolar transistor 3, the voltage Veb between the emitter and the base of the PNP-type bipolar transistor becomes a negative voltage. That is, a reverse bias is applied to the PN junction associated with the emitter-base of the PNP-type bipolar transistor 3, and the PNP-type bipolar transistor 3 is turned off.

Therefore, when changing a relative relationship of the magnetization arrangement of the MTJ element 1 from P state to AP state, it is sufficient to consider operations of the MTJ element 1 and the NPN-type bipolar transistor 2 under conditions that the base potential Vb (the potential in the word line WL) is higher than the emitter voltage Ve (the potential in the node N1) (i.e., Vb>Ve).

Here, the emitter voltage Ve is higher than the ground potential Vss due to a voltage drop arising from the MTJ element. Additionally, the emitter voltage Ve is modulated by the base voltage Vb since it is dependent on an amount of a current flowing through the node N1.

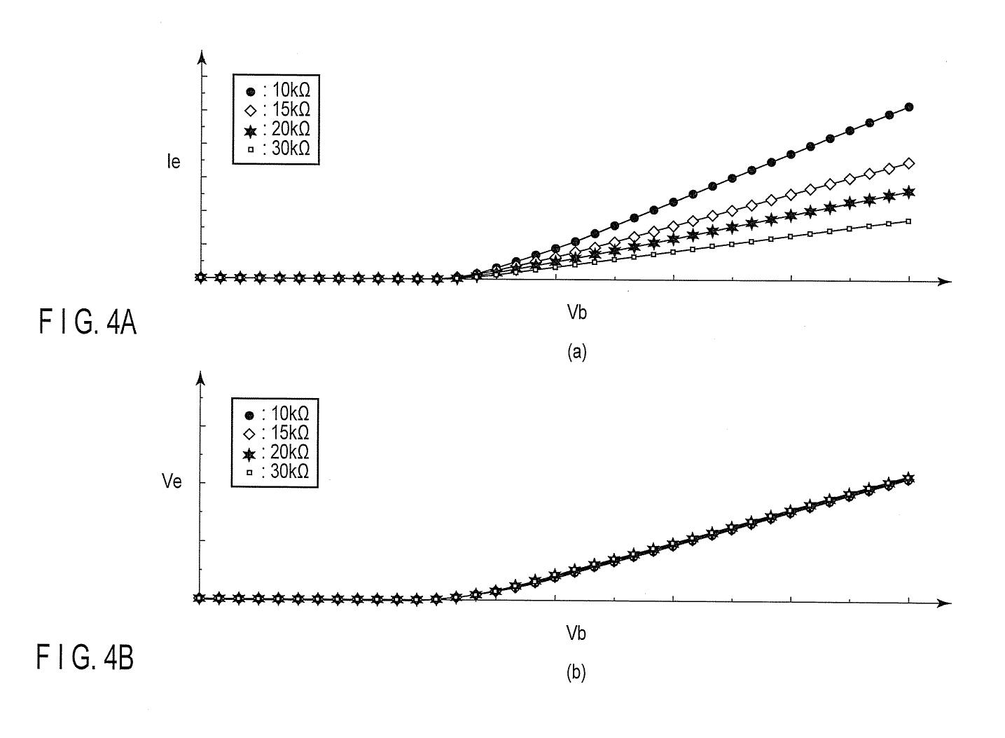

Relationships between the base voltage Vb and the emitter voltage Ve and between the base voltage Vb and the emitter current Ie in the NPN-type bipolar transistor 2 in FIG. 2B will now be described with reference to FIGS. 4A and 4B.

Each of FIGS. 4A and 4B shows a simulation result concerning a circuit of the NPN-type bipolar transistor 2 and the MTJ element 1 in the memory cell MC. In FIGS. 4A and 4B, the resistance value of the MTJ element 1 is set to an arbitrary value, and the operation model of the bipolar transistor is set to an appropriate model. It is to be noted that the emitter voltage Ve and the emitter current Ie when the base voltage Vb is swept in the simulation of FIGS. 4A and 4B are shown.

The collector voltage Vc of the NPN-type bipolar transistor 2 is set to the power supply voltage Vdd (approximately 1.0 V to 2.0 V), and the base voltage Vb is changed from 0 V to the power supply voltage Vdd. The potential in the bit line BL is set to the ground potential (0 V). Moreover, the resistance value of the MTJ element 1 is changed as each parameter. The resistance value of the MTJ element 1 is set to 10 kΩ, 15 kΩ, 20 kΩ, and 30 kΩ, respectively.

FIG. 4A shows a relationship between the base voltage Vb and the emitter current Ie in the NPN-type bipolar transistor 2. In FIG. 4A, an abscissa of a graph is associated with the base voltage Vb, and an ordinate of the graph is associated with the emitter current Ie.

FIG. 4B shows a relationship between the base voltage Vb and the emitter voltage Ve in the NPN-type bipolar transistor 2. In FIG. 4B, an abscissa of a graph is associated with the base voltage Vb, and an ordinate of the graph is associated with the emitter voltage Ve.

As shown in FIG. 4A, when the base voltage Vb is the power supply voltage Vdd, the emitter current Ie has a maximum value. When the resistance value of the MTJ element 1 increases, an absolute value of the emitter current Ie is reduced.

Moreover, as shown in FIG. 4B, when the emitter current Ie flows, the emitter voltage Ve increases. Additionally, like FIG. 3B, an intensity and a change tendency of the emitter voltage Ve are hardly dependent on the resistance value of the MTJ element 1.

As represented by the simulation result in each of FIGS. 4A and 4B, when the base voltage Vb is the power supply voltage Vdd, a base-emitter voltage Vbe has a maximum value, and the emitter current Ie has a maximum value.

Therefore, when changing the magnetization arrangement of the MTJ element from P state to AP state, it is preferable to set the potential in the word line WL to approximately the power supply voltage Vdd with respect to the potential in the bit line BL which is approximately equal to the ground potential. As a result, the efficiency of writing data by using an output from the NPN-type bipolar transistor 2 can be improved.

In operations of two bipolar transistors which are of a regular push-pull type, a voltage between an emitter and a base and a voltage between a base and a collector are fixed.

On the other hand, in the NPN-type bipolar transistor 2 and the PNP-type bipolar transistor 3 in the memory cell MC, the base voltage is modulated at the time of operation, and the voltage between the emitter and the base and the voltage between the base and the collector vary depending on a direction and an intensity of the current supplied to the resistance change type memory element.

In the memory according to this embodiment, each of the bipolar transistors 2 and 3 can output the write current higher than the switching threshold current of the MTJ element 1 and supply the write current having a margin assured for the switching threshold current of the MTJ element 1 to the MTJ element in the memory cell. Further, assuring the margin of the write current results in improvement of the reliability of the write operation.

As described above, in the resistance change type memory according to this embodiment, providing the two bipolar transistors 2 and 3 in the memory cell enables generating the currents I_{W-P} and I_{W-AP} bi-directionally flowing with respect to the MTJ element in accordance with data to be written.

(b-2) Read Operation

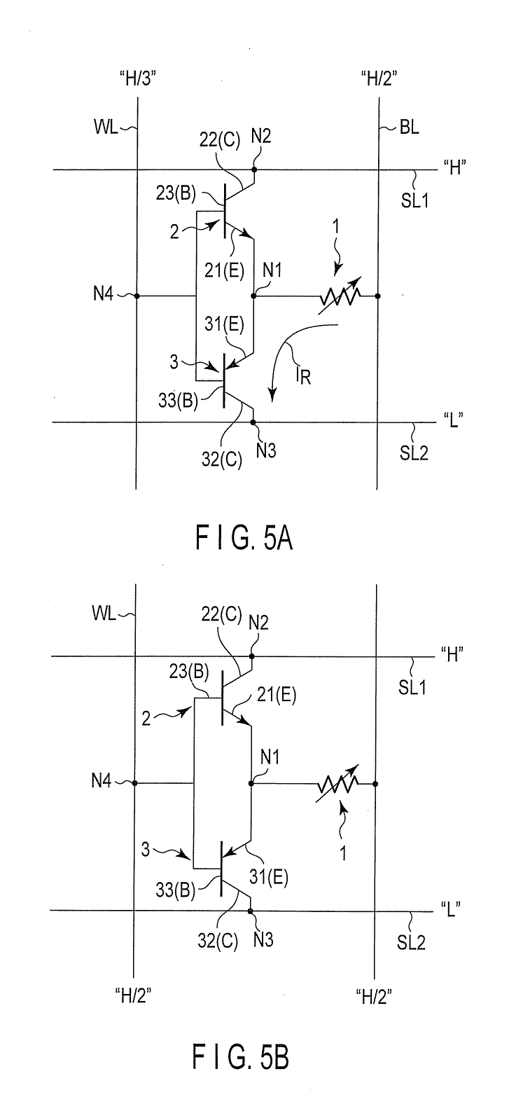

A data reading operation of the resistance change type memory according to this embodiment will now be described with reference to FIG. 5A. Description will be given as to an example that a read current I_{R} is flowed in a direction, which is the same as that when changing the magnetization arrangement of the MTJ element 1 from AP state to P state, in a read operation of an MRAM according to this embodiment.

In the read operation of the MRAM, a current is flowed through the MTJ element 1 like the example of writing data, but a current value of the read current I_{R} is set to be smaller than the switching threshold current of the MTJ element 1 so that data stored in the MTJ element 1 cannot be destroyed (cannot be rewritten).

For example, as shown in FIG. 5A, the potential in the bit line BL is set to approximately Vdd/2, and the potential in the word line is set to 0 V to approximately Vdd/3.

In this case, since the emitter voltage Ve is higher than the base voltage Vb, the PNP-type bipolar transistor 3 is turned on, and the NPN-type bipolar transistor 2 is turned off.

An intensity of the current flowing through the bit line BL or an intensity of the potential in the read node N3 varies in accordance with a resistance value of the MTJ element 1. This intensity of the current/potential is detected, data stored in the MTJ element 1 is judged.

Here, an example of supplying the read current I_{R} to the MTJ element by using the PNP-type bipolar transistor 3 which is in the ON state will be described. It is to be noted that an output current from the NPN-type bipolar transistor 2 may be determined as the read current I_{R} by controlling the potentials in the bit line and the word line, turning off the PNP-type bipolar transistor 3, and turning on the NPN-type bipolar transistor 2. However, a current value of the read current from the NPN-type bipolar transistor 2 is set to a value smaller than the switching threshold current of the MTJ element 1 in the read operation.

Even in a situation that the two bipolar transistors 2 and 3 are provided in the memory cell MC in this manner, an intensity of an output current from each bipolar transistor can be controlled by controlling the potentials in the bit line BL and the word line WL. Therefore, in the memory according to this embodiment, an erroneous write operation caused by the read current I_{R} can be suppressed to read data from the MTJ element 1.

Therefore, in the resistance change type memory according to this embodiment, data can be read from the MTJ element in the memory cell MC including the two bipolar transistors 2 and 3.

(b-4) Data Holding Operation

A data holding operation of the resistance change type memory according to this embodiment will now be described with reference to FIG. 5B.

For example, when setting the memory cell to a data holding state (which will be also referred to as a standby state), the potential (the voltage) in the power supply line SL1 is set to the power supply potential Vdd, and the potential in the ground line SL2 is set to the ground potential Vss.

When the potentials in the emitters 21 and 31 of the NPN-type/NPN-type bipolar transistors 2 and 3 are substantially equal to the potentials in the bases 23 and 33 of the NPN-type/PNP-type bipolar transistors 2 and 3, i.e., when a potential difference between the connection node N1 and the connection node N4 is substantially 0, both the NPN-type bipolar transistor 2 and the PNP-type bipolar transistor 3 are turned off.

When the potential applied to the bit line BL is set to the same intensity as that of the potential applied to the word line WL, the current is hardly supplied to the MTJ element 1. Therefore, when the potential difference between the bit line BL and the word line WL is set to 0, data can be held in the MTJ element 1 without writing data into the MTJ element 1.

Incidentally, in a case of a bipolar transistor using silicon (Si), each bipolar transistor 2 or 3 is not turned on unless a voltage of 0.6 V or above is applied in a forward direction with respect to a pn junction between an emitter (E) and a base (B).

The potentials in the bit line BL and the word line WL may be set to 0 V to set a potential difference between the bit line and the word line to 0 V. However, it is preferable to supply an intermediate potential (which is Vdd/2 in the following description) of approximately Vdd/3 to Vdd/2 to both the bit line BL and the word line WL. As a result, in the data holding state of the memory cell MC, the bit line BL and the word line WL are charged with the intermediate potential Vdd/2. Therefore, a reduction in operating speed of the memory caused by interconnect delay can be suppressed.

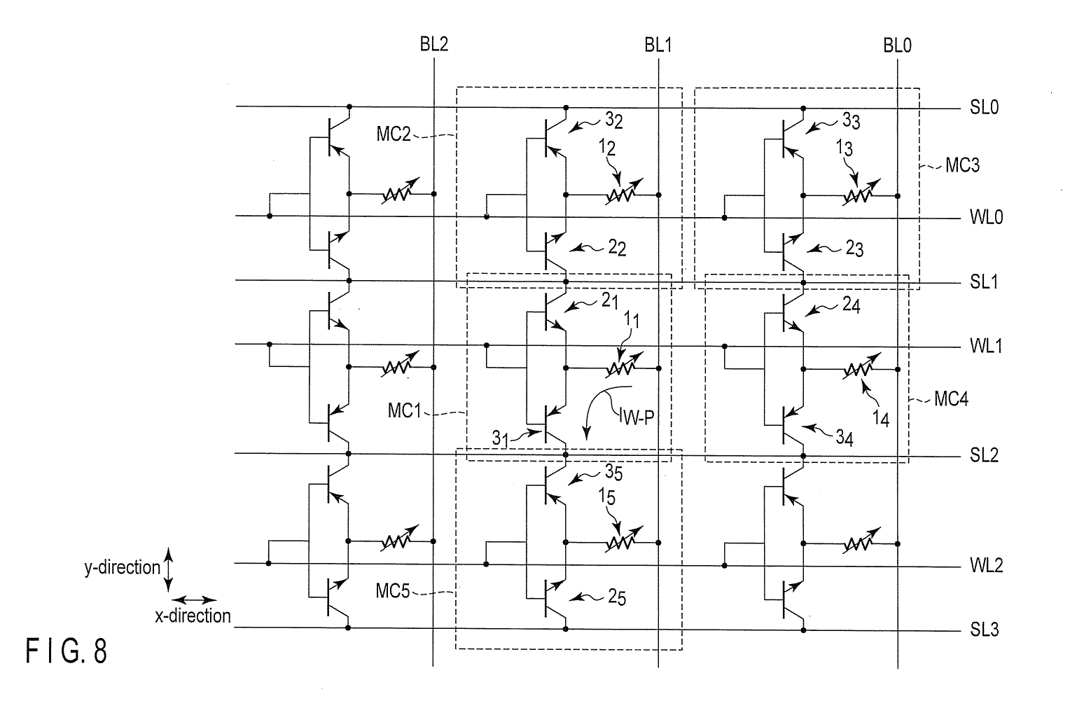

When the memory cell array is formed by using the memory cells MC according to this embodiment (see FIG. 8), since an interconnect length of each of the bit line BL and the word line WL becomes long, charging the bit line and the word line with the intermediate potential Vdd/2 is effective for improving operation characteristics of the resistance change type memory. Therefore, operations after the data holding state of the memory 11 can be accelerated by charging the bit line/word line at the time of holding data.

### (c) Structure

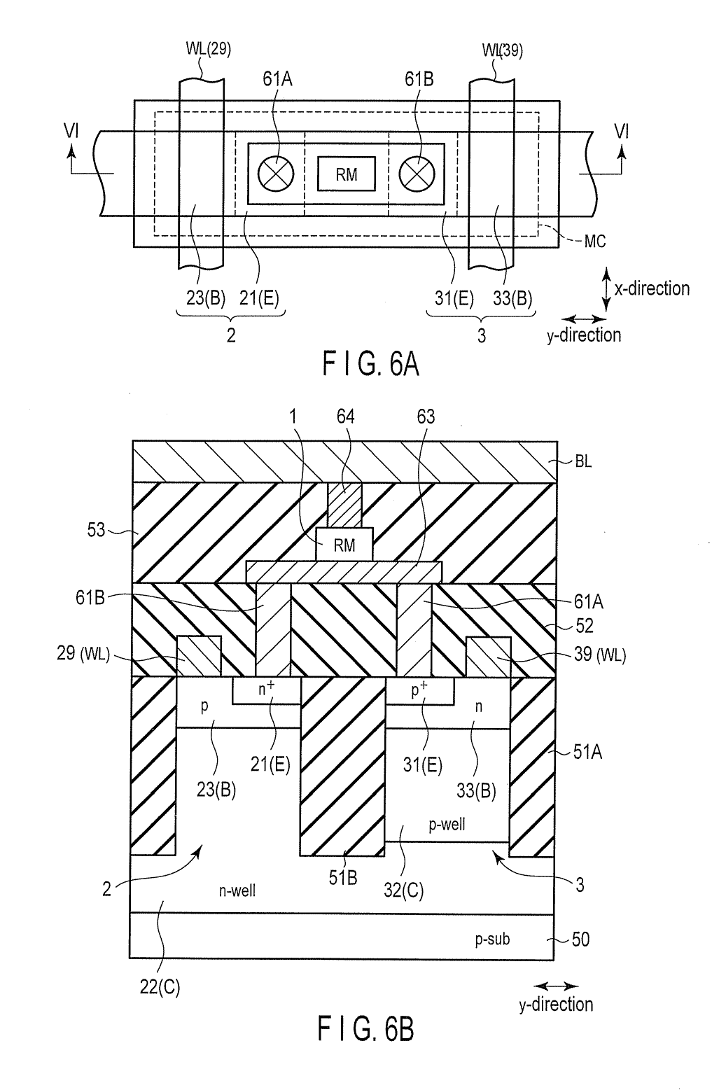

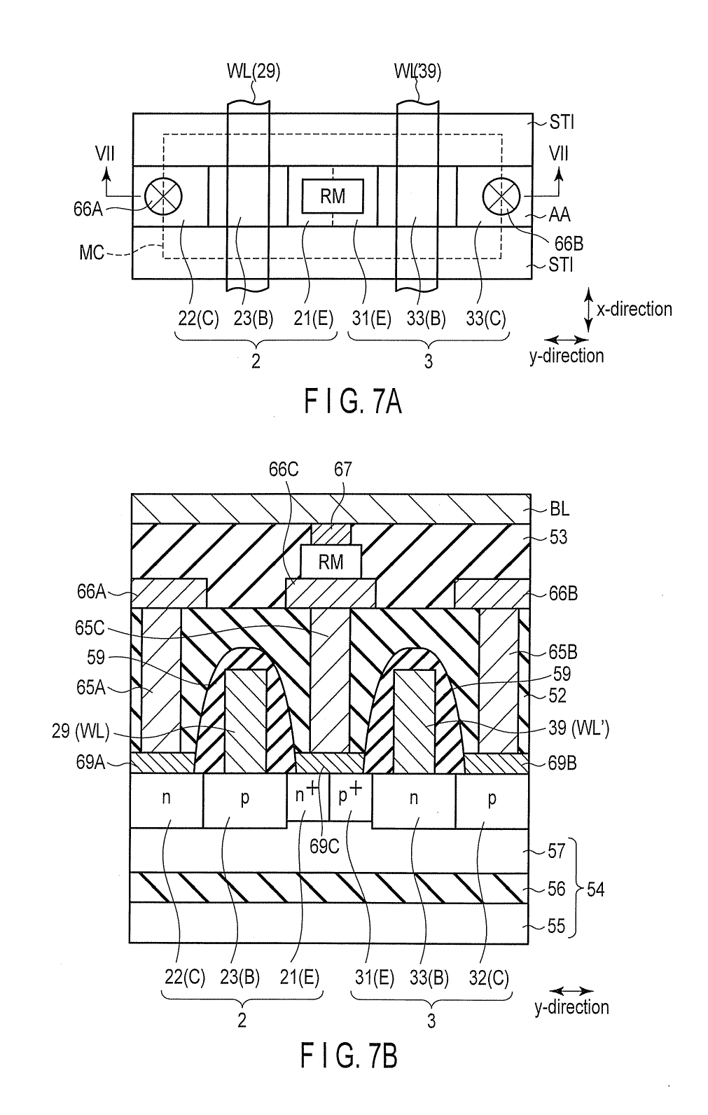

A structure of the memory cell MC of the resistance change type memory according to this embodiment will now be described with reference to FIGS. 6A, 6B, 7A, and 7B.

### (c-1) Structural Example 1

Structural Example 1 of the memory cell MC of the resistance change type memory according to this embodiment will now be described with reference to FIGS. 6A and 6B.

FIG. 6A shows a planar structure of one memory cell MC in Structural Example 1. FIG. 6B shows a cross-sectional structure taken along a line VI-VI in FIG. 6A.

In the memory cell MC shown in FIGS. 6A and 6B, each bipolar transistor 2 or 3 has a planar structure.

As shown in FIGS. 6A and 6B, the bit line BL extends in the y-direction above a forming region of the bipolar transistors 2 and 3 (which will be referred to as a bipolar transistor forming region hereinafter). The word lines WL and WL′ extend in the x-direction crossing the extending direction of the bit line.

The two bipolar transistors 2 and 3 in the memory cell MC are formed of impurity semiconductor layers 21, 22, 23, 31, 32, and 33 in a semiconductor substrate 50.

The semiconductor substrate 50 is, e.g., a p-type (a second conductivity type) semiconductor substrate (a p-type silicon substrate).

Isolation insulating films 51A and 51B are buried in trenches in the semiconductor substrate 50. The isolation insulating films 51A and 51B partition the bipolar transistor forming regions and electrically separate an NPN-type bipolar transistor forming region (a first semiconductor region) from a PNP-type bipolar transistor forming region (a second semiconductor region).

An n-type (a first conductivity type) well region 22 is provided in the semiconductor substrate 50.

The n-type well region 22 is used as the collector (C) of the NPN-type bipolar transistor 2. In the NPN-type bipolar transistor forming region, the p-type impurity layer 23 is provided in the n-type well region 22. The p-type impurity layer 23 is used as the base (B) of the NPN-type bipolar transistor 2. The n⁺-type impurity layer 21 is provided in the p-type impurity layer 23. The n⁺-type impurity layer 21 is used as the emitter (E) of the NPN-type bipolar transistor 2.

In the transistor forming region where the PNP-type bipolar transistor 3 is formed, the p-type well region 32 is provided in the n-type well region 22. The p-type well region 32 is used as the collector (C) of the PNP-type bipolar transistor 3. The n-type impurity layer 33 is provided in the p-type well region 32. The n-type impurity layer 33 is used as the base (B) of the PNP-type bipolar transistor 3. The p⁺-type impurity layer 31 is provided in the n-type impurity layer 33. The p⁺-type impurity layer 31 is used as the emitter (E) of the PNP-type bipolar transistor 3.

The n-type well region 22 as the collector of the NPN-type bipolar transistor 2 will be referred to as the n-type collector layer 22 hereinafter. The p-type impurity layer 23 as the base of the NPN-type bipolar transistor 2 will be referred to as the p-type base layer 23. Further, the n⁺-type impurity layer 21 as the emitter of the NPN-type bipolar transistor 2 will be referred to as the n⁺-type emitter layer 21.

The p-type well region 32 as the collector of the PNP-type bipolar transistor 3 will be referred to as the p-type collector layer 32. The n-type impurity layer 33 as the base of the PNP-type bipolar transistor 2 will be referred to as the n-type base layer 33. The p⁺-type impurity layer 31 as the emitter of the PNP-type bipolar transistor 3 will be referred to as the p⁺-type emitter layer 31.

In the NPN-type bipolar transistor forming region, the p-type base layer 23 is interposed between a bottom surface of the n⁺-type emitter layer 21 and an upper surface of the n-type collector layer 22. An upper surface of the p-type base layer 23 is exposed on the surface of the substrate 50, and the upper surface of the p-type base layer 23 is adjacent to an upper surface of the n⁺-type emitter layer 21 in the y-direction on the surface of the substrate 50.

In the PNP-type bipolar transistor forming region, the n-type base layer 33 is interposed between a bottom surface of the p⁺-type emitter layer 31 and an upper surface of the p-type collector layer 32. An upper surface of the n-type base layer 33 is exposed on the surface of the substrate 50, and the upper surface of the n-type base layer 33 is adjacent to an upper surface of the p⁺-type emitter layer 31 in the y-direction on the surface of the substrate 50.

The two emitter layers 21 and 31 are adjacent to each other in the y-direction to sandwich the isolation insulating film 51B therebetween.

A contact plug 61B is provided on the n⁺-type emitter layer 21. Further, a contact plug 61A is provided on the p⁺-type emitter layer 31. The contact plugs 61A and 61B are buried in a first interlayer insulating film (e.g., SiO₂) 52 that covers the surface of the semiconductor substrate 50. For example, tungsten (W) or molybdenum (Mo) is used for the contact plugs 61A and 61B.

An intermediate interconnect 63 is provided on the two contact plugs 61A and 61B. The intermediate interconnect 63 is continuous on the two contact plugs 61A and 61B to connect the two contact plugs 61A and 61B to each other. The n-type emitter layer 21 is electrically connected to the p-type emitter layer 31 by the contact plugs 61A and 61B and the intermediate interconnect line 63. As a result, the emitters of the two bipolar transistors 2 and 3 are connected to each other. The intermediate interconnect line 63 is formed by using a conductor, e.g., aluminum (Al), copper (Cu), titanium (Ti), or a titanium nitride (TiN).

The MTJ element 1, the intermediate interconnect line 63, and a via plug 64 are covered with a second interlayer insulating film 53. The bit line BL is provided on the via plug 64 and the interlayer insulating film 53.

The resistance change type memory element (e.g., the MTJ element) 1 is provided on the intermediate interconnect 63. The via plug 64 is provided on the MTJ element 1. The bit line BL is connected to the other end of the MTJ element 1 through the via plug 64. One end of the MTJ element 1 is connected to the n-type emitter layer 21 and the p-type emitter layer 31 through the intermediate interconnect 63 and the contact plugs 61A and 61B.

For example, according to the connection relationship of the MTJ element 1, the reference layer 10A is arranged on the intermediate interconnect 63 through the lower electrode 18. The tunnel barrier layer 11A is arranged on the reference layer 10A. The recording layer 12A is arranged on the tunnel barrier layer 11A. Furthermore, the via plug 64 is provided on the upper electrode 19 the recording layer 12A. The reference layer 10A is connected to the emitter layers 21 and 31 through the intermediate interconnect 63 and the contact plugs 61A and 61B, and the recording layer 12A is connected to the bit line BL through the via plug 64.

The MTJ element 1 is arranged above the isolation insulating film 51B to separate the emitter layers 21 and 31 from each other, for example.

A first interconnect 29 is provided on the p-type base layer 23. A second interconnect 39 is provided on the n-type base layer 33. The interconnects 29 and 39 are directly in contact with the base layers 23 and 33. The interconnects 29 and 39 are laid out on the semiconductor substrate 50 to sandwich the contact plugs 61A and 61B in the y-direction.

The interconnects 29 and 39 extend in, e.g., the x-direction. The interconnects 29 and 39 are formed by using, e.g., polysilicon, silicide, a metal, or a laminated body including these materials.

The two interconnects 29 and 39 are connected to each other through the contact plugs or the intermediate interconnect on at least one end of the extending direction of these interconnects. The interconnects 29 and 39 are interconnects to connect, e.g., the base layers 23 and 33 to the word lines. Therefore, the interconnects 29 and 39 substantially function as the word lines WL and WL′, and the two interconnects 29 and 39 form one pair of word lines. The interconnects 29 and 39 will be also referred to as the word lines WL and WL′ hereinafter for ease of explanation. It is to be noted that a sidewall insulating film may be provided on a side surface of each of the interconnects 29 and 39.

The n-type collector layer 22 and the p-type collector layer 32 are connected to the power supply line SL1 on the high-potential (Vdd) side and the ground line SL2 on the low-potential (Vss) side through a triple well structure. The n-type well region 22 as the n-type collector layer 22 is also used as the power supply line SL1, and the p-type well region 32 as the p-type collector layer 32 is also used as the ground line SL2.

In the configuration shown in FIGS. 6A and 6B, the number of contacts through which a current flows is the same both in a case that the current is supplied from the bit line BL side toward the substrate 50 side and a case that the current is supplied from the substrate 50 side toward the bit line BL side with respect to the MTJ element 1. As a result, even if the write operation for the memory cell is an operation of bi-directionally flowing the write current to the MTJ element 1, a variation in the write current due to parasitic resistance of each contact can be suppressed.

A manufacturing method of the memory cell according to this Structural Example 1 will be described later.

As explained above, in this Structural Example 1, the bipolar transistors 2 and 3 in the memory cell MC have the planar structure. Therefore, the bipolar transistors 2 and 3 of the memory cell MC according to this Structural Example 1 can be formed by using the impurity semiconductor regions 21, 22, 23, 31, 32, and 33 provided in the semiconductor substrate 50. Therefore, the bipolar transistors 2 and 3 of the memory cell MC can be formed by using a relatively simple manufacturing process, thereby reducing a manufacturing cost.

### (c-2) Structural Example 2

Structural Example 2 of the memory cell MC in the resistance change type memory according to this embodiment will now be described with reference to FIGS. 7A and 7B. It is to be noted that, in this Structural Example 2, like reference numerals denote members equal to those in Structural Example 1, and detailed description of these members will be given as required.

FIG. 7A shows a planar structure of one memory cell MC in Structural Example 2. FIG. 7B shows a cross-sectional structure taken along a line VII-VII in FIG. 7A.

In the memory cell MC depicted in FIGS. 7A and 7B, bipolar transistors 2 and 3 have a lateral structure.

The bipolar transistors 2 and 3 having the lateral structure are provided on an SOI substrate 54.

The SOI substrate 54 is formed of an insulating film 56 on a semiconductor substrate 55 and a semiconductor layer (which will be referred to as an SOI layer) 57 on the insulating film 56.

In the memory cell using the bipolar transistors having the lateral structure, if a well region is provided in the SOI layer 57, a leak current cannot be reduced. Therefore, by a usage of an intrinsic semiconductor layer for the SOI layer 57, impurity layers are electrically separated from each other. The impurity concentration of the intrinsic SOI layer 57 is sufficiently lower than the impurity concentration of each of a collector layer, a base layer, and an emitter layer.

Collector layers 22 and 32, base layers 23 and 33, and emitter layers 21 and 31 of the respective bipolar transistors 2 and 3 are provided in the SOI layer 57.

A region AA in which the respective bipolar transistors 2 and 3 are formed is continuous in the y-direction. The bipolar transistor forming region AA is sandwiched between two isolation regions STI in the x-direction.

A silicide layer 69A is provided on the n-type collector layer 22 of the NPN-type bipolar transistor 2. A contact plug 65A is provided on the silicide layer 69A. The contact plug 65A is connected to an interconnect 66A. The interconnect 66A is connected to, e.g., a power supply Vdd. The interconnect 66A is used as a power supply line SL1. The interconnect 66A is made of, e.g., a metal. The interconnect 66A extends in, e.g., the x-direction. In this manner, the n-type collector layer 22 is connected to the metal power supply line SL1.

The p-type base layer 23 of the NPN-type bipolar transistor 2 is provided between the n-type collector layer 22 and the n⁺-type emitter layer 21 in the SOI layer 57. A interconnect 29 is provided on the p-type base layer 23.

A silicide layer 69B is provided on the p-type collector layer 32 of the PNP-type bipolar transistor 3. A contact plug 65B is provided on the silicide layer 69B. The contact plug 65B is connected to an interconnect 66B. The interconnect 66B is connected to, e.g., a ground potential Vss, and the interconnect 66B is used as a ground line SL2. The interconnect 66B is made of, e.g., a metal. The interconnect 66B extends in, e.g., the x-direction. In this manner, the p-type collector layer 32 is connected to the metal ground line SL2.

The n-type base layer 33 of the PNP-type bipolar transistor 3 is provided between the p-type collector layer 32 and the p⁺-type emitter layer 31 in the SOI layer 57. A interconnect 39 is provided on the n-type base layer 33.

The n-type emitter layer 21 and the p-type emitter layer 31 are adjacent to each other in the y-direction in the SOI layer 57. The two emitter layers 21 and 31 are sandwiched between the two base layers 23 and 33 in the y-direction. It is to be noted that the n⁺-type emitter layer 21 is directly in contact with the p⁺-type emitter layer 31 in the example shown in FIGS. 7A and 7B, but an intrinsic semiconductor layer (an SOI layer) may be interposed between the n⁺-type emitter layer 21 and the p⁺-type emitter layer 31.

A silicide layer 69C is provided on the n-type emitter layer 21 and the p-type emitter layer 31. The silicide layer 69 is continuous on the n-type emitter layer 21 and on the p-type emitter layer 31 in the y-direction. One contact plug 65C is provided on the two emitter layers 21 and 31 through the silicide layer 69C.

An intermediate interconnect 66C is provided on the contact plug 65C. The MTJ element (the resistance change type memory element) 1 is provided on the intermediate interconnect 66C. The MTJ element 1 is connected to the bit line BL through a via plug 67.

In this manner, the two emitter layers 21 and 31 are connected to the MTJ element 1 through the common contact plug 65C.

The contact plug 65C on the emitter layers 21 and 31 is laid out on the SOI substrate 54 in such a manner that the contact plug 65C is sandwiched between the interconnects 29 and 39 on the two base layers 23 and 33 in the y-direction.

The MTJ element 1 is arranged above the two emitter layers 21 and 31 to cut across the two emitter layers 21 and 31.

The interconnects 29 and 39 on the base layers 23 and 33 are covered with a sidewall insulating film 59. The sidewall insulating film 54 is formed by using, e.g., a silicon nitride film or a silicon oxide film. For example, the sidewall insulating film 54 is formed on each of the interconnects 29 and 39 in such a manner that a lower end of the sidewall insulating film 54 cuts across a boundary portion between the base layer 23 or 33 and the collector layers 22 and 32. For example, the sidewall insulating film 54 is formed on the interconnects 29 and 39 in such a manner that the lower end of the sidewall insulating film 54 cuts across a boundary portion between the base layers 23 and 33 and the emitter layers 21 and 31. When the sidewall insulating film 54 covers each boundary between the base layer 23 or 33 and the other layers 21, 31, 22 or 32 in this manner, the base layers 23 and 33 can be prevented from being electrically connected to the silicide layers 69A, 69B, and 69C.

It is preferable to reduce dimensions of the base layers 23 and 33 in the y-direction in order to improve characteristics of the bipolar transistors Tr. When the dimensions of the collector layers 22 and 33 in the y-direction or the dimensions of the base layers 23 and 33 in the y-direction are represented by a unit “F”, the dimensions of the emitter layers 21 and 31 in the y-direction are represented by, e.g., “F/2”.

To prevent the interconnects 29 and 39 from coming into contact with the emitter layers/collector layers, it is preferable for the dimensions of the interconnects (the word lines) 29 and 39 in the y-direction to be not greater than the dimensions of the base layers 23 and 33 in the y-direction.

A manufacturing method of the memory cell according to this Structural Example 2 will be described later.

The bipolar transistors 2 and 3 having the lateral structure do not supply currents to the MTJ element 1 through a well region, as opposed to the bipolar transistors having the planar structure. Therefore, the two bipolar transistors 2 and 3 in the memory cell MC do not have to be separated from each other through an isolation region (an isolation insulating film). Therefore, an occupied area (a cell size) of the memory cell MC can be reduced by decreasing an area of the isolation region.

Furthermore, differing from the example using the bipolar transistors having the planar structure, the bipolar transistors 2 and 3 having the lateral structure according to this Structural Example 2 do not have to separate a well region at a deep position in the substrate. Therefore, when the bipolar transistors having the lateral structure are used, a dimension for separating the well region (an element separation width) does not have to be assured, and a dimension of the memory cell MC in the y-direction can be reduced.

As described above, in this Structural Example 2, the bipolar transistors 2 and 3 in the memory cell MC have the lateral structure. Therefore, the bipolar transistors 2 and 3 of the memory cell MC according to this Structural Example 2 enable the cell size of the memory cell to be reduced as compared with the bipolar transistors 2 and 3 having the planar structure.

### (2) Example

A memory cell array using the memory cell MC will now be explained as an example of the resistance change type memory according to this embodiment with reference to FIGS. 8 to 22B. It is to be noted that equal or like reference numerals denote members equal to the members depicted in FIGS. 1 to 7B, and detailed description thereof will be given as required.

### (a) Circuit Configuration

A circuit configuration of a memory cell array of the resistance change type memory according to this embodiment will be explained with reference to FIG. 8.

FIG. 8 is an equivalent circuit schematic of the memory cell array of the resistance change type memory according to this embodiment.

As shown in FIG. 8, the memory cell array includes memory cells MC1, MC2, MC3, MC4, MC5, . . . .

Additionally, bit lines BL0, BL1, and BL2 and word lines WL0, WL1, and WL2 are provided in the memory cell array.

The bit lines BL0, BL1, and BL2 extend in the y-direction (a column direction). The respective bit lines BL0, BL1, and BL2 are adjacent to each other in the x-direction (a row direction). The word lines WL0, WL1, and WL2 extend in the x-direction. The respective word lines WL1, WL2, and WL3 are adjacent to each other in the y-direction.

Power supply lines SL1 and SL3 and ground lines SL0 and SL2 extend in, e.g., the x-direction.

A power supply voltage Vdd is applied to the power supply lines SL1 and SL3, and a ground potential Vss is applied to the ground lines SL0 and SL2.

In the memory cell array, the memory cells MC1, MC2, MC3, and MC4 aligned in the y-direction (a common column) are connected to the common bit lines BL0, BL1, and BL2. Further, in the memory cell array, the memory cells MC1, MC2, MC3, and MC4 aligned in the x-direction (a common row) are connected to the common word lines WL0, WL1, and WL2.

Furthermore, in the memory cell array, the memory cells aligned in the y-direction (the common row) are connected to the common power supply lines SL1 and SL3 and the common ground lines SL0 and SL2. The memory cells MC1, MC2, MC3, and MC4 adjacent to each other in the y-direction share the power supply lines SL1 and SL3 and the ground lines SL0 and SL2.

For example, the power supply line SL1 is shared by the memory cells MC1 and the memory cell MC4 which are adjacent to each other in the y-direction. An NPN-type bipolar transistor 2₁ in the memory cell MC1 is adjacent to an NPN-type bipolar transistor 2₂ in the memory cell MC2 in the y-direction. A collector of the NPN-type bipolar transistor 2₁ in the memory cell MC1 and a collector of an NPN-type bipolar transistor 2₄ in the memory cell MC4 are connected to the common power supply line SL1. The collector of the NPN-type bipolar transistor 2₁ in the memory cell MC1 is connected to a collector of the NPN-type bipolar transistor 2₂ in the memory cell MC2 through the power supply line SL1.

For example, the ground line SL2 is shared by the memory cell MC1 and the memory cell MC5 that are adjacent to each other in the y-direction. A PNP-type bipolar transistor 3₁ in the memory cell MC1 is adjacent to a PNP-type bipolar transistor 3₅ in the memory cell MC5 in the y-direction. A collector of the PNP-type bipolar transistor 3₁ in the memory cell MC1 and a collector of the PNP-type bipolar transistor 3₅ in the memory cell MC5 are connected to the common ground line SL2. The collector of the PNP-type bipolar transistor 3₁ in the memory cell MC1 is connected to the collector of the PNP-type bipolar transistor 3₅ in the memory cell MC5 through the ground line SL2.

The memory cell MC1 and the memory cell MC2 have a mirror image relationship with the power supply line SL1 being used as an axis of symmetry. Further, the memory cell MC1 and the memory cell MC5 have a mirror image relationship with the ground line SL2 at a boundary. In this embodiment, the mirror image relationship means that the memory cells adjacent to each other in the y-direction have a line-symmetric relationship with the power supply line/ground line at the center or the memory cells adjacent to each other have a relationship in which they are inverted in the y-direction.

When the memory cells are arranged in the memory cell array in such a manner that the memory cells adjacent to each other in the y-direction have the mirror image relationship in this manner, the memory cells adjacent to each other can share the power supply lines SL1 and SL3 and the ground lines SL0 and SL2. As a result, an area of the memory cell array can be reduced and the interconnect layout is simplified.

### (b) Operations

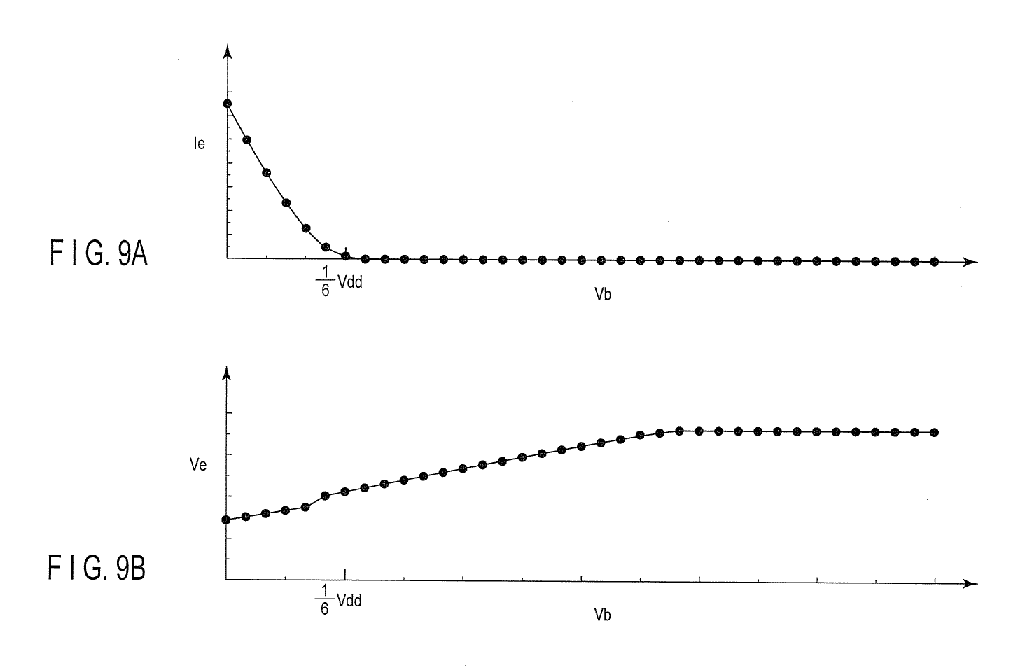

Operations of the memory cell array shown in FIG. 8 will now be described with reference to FIGS. 9A, 9B, 10A, 10B, 11A, and 11B.

Here, a write operation for a memory cell selected as an operation target (which will be referred to as a selected hereinafter) will be exemplified to describe the operation of the memory cell array. Memory cells other than the selected cell in the memory cell array will be referred to as non-selected cells.

In this example, the selected cell is the memory cell MC1 in the memory cell array shown in FIG. 8. Here, description will be given as to an example of using an output current (an emitter current) from the PNP-type bipolar transistor 3₁, which is in the ON state, to write data into the resistance change type memory element 1₁ in the selected cell MC1. Further, drive states of the non-selected cells MC2, MC3, and MC4 adjacent to the selected cell MC1 in the y-direction or the x-direction will be also explained.

The bit line and the word line connected to the selected cell will be referred to as a selected bit line and a selected word line hereinafter. The bit lines other than the selected bit line will be referred to as non-selected bit lines, and word lines other than the selected word line will be referred to as non-selected word lines. Further, in the non-selected cells, a non-selected cell connected to the selected bit line and the non-selected word line or a non-selected cell connected to the selected word line and the non-selected bit line may be referred to as a half-selected cell.

At the time of a write operation, potentials in the power supply lines SL1 and SL3 are set to a power supply voltage Vdd, and potentials in the ground lines SL0 and SL2 are set to the ground potential Vss. It is to be noted that potentials in the power supply lines SL1 and SL3 and the potentials in the ground lines SL0 and SL2 can be changed to drive the memory cell array. However, when the potentials in the power supply line/ground line are changed, there is a tendency that consumption power increases and operations of the memory cell array become complicated. Therefore, it is preferable for the potentials in the power supply lines SL1 and SL3 and the ground lines SL0 and SL2 to be fixed while supplying the power supply voltage to the chip.

Therefore, in a state that the potentials in the power supply lines/ground lines SL0, SL1, SL2, and SL3 are set to predetermined values, predetermined data is written into the selected cell by adjusting potentials in the bit lines BL0, BL1, and BL2 and the word lines WL0, WL1, and WL2, respectively, and operations of the entire memory cell array are controlled to prevent the data from being written into the non-selected cells.

It is to be noted that, since the potentials in the bit lines BL0, BL1, and BL2 change between an “H” level (a state “1”) and an “L” level (a state “0”) in the write operation, an “H/2” level (which will be also referred to as a state “0.5”) is preferable as the potential in each bit line in a data holding state, for example. The “H/2” level is, e.g., a potential of approximately Vdd/2.

A state that the potentials in the bit lines BL0, BL1, and BL2 are set to the “H/2” level in this manner is determined as a memory cell standby state, whereby times for charging and discharging the bit lines BL0, BL1, and BL2 can be reduced.

When the MTJ element 1₁ has the same connection relationship as that in the example shown in FIG. 2A and FIG. 2B with respect to the bit line BL1 and the bipolar transistors 2₁ and 3₁, an output current (an emitter current) from the PNP-type bipolar transistor 3₁ changes the magnetization arrangement of the MTJ element from AP state to P state.

When the potential in the selected bit line BL1 is set to the “H” level (Vdd) and the potential in the selected word line WL1 is set to the “0” level, the emitter current in the PNP-type bipolar transistor 3₁ increases.

However, in regard to the non-selected cell MC4 adjacent to the selected cell MC1 in the x-direction, the potentials in the bit line and the word line must be considered. That is, even in the non-selected cell MC4 connected to the selected word line WL1, currents from the bipolar transistors 2₄ and 3₄ may be generated, and data may be possibly written into the MTJ element 1₄ in the non-selected cell MC4.

The non-selected cell (the half-selected cell) MC4 adjacent to the selected cell MC1 in the x-direction is connected to both the selected word line WL1 and the non-selected bit line BL0 which is at the “H/2” level. Therefore, as shown in FIGS. 3A and 3B, the emitter current associated with the potential in the non-selected bit line BL0 is generated from the PNP-type bipolar transistor 3₄ in the half-selected cell MC4.

FIGS. 9A and 9B show relationships between a base voltage and an emitter current and between the base voltage and an emitter voltage in the PNP-type bipolar transistor when the potential in the bit line BL is at the “H/2” level (=Vdd/2).

FIG. 9A shows a relationship between a base voltage Vb and an emitter current Ie in the PNP-type bipolar transistor. FIG. 9B shows a relationship between the base voltage Vb and an emitter voltage Ve in the PNP-type bipolar transistor.

In FIG. 9A, an abscissa of a graph is associated with the base voltage Vb, and an ordinate of the graph is associated with the emitter current Ie. In FIG. 9B, an abscissa of a graph is associated with the base voltage Vb, and an ordinate of the graph is associated with the emitter voltage Ve.

As shown in FIGS. 9A and 9B, in a situation that the potential in the bit line is approximately Vdd/2, the emitter current Ie of the PNP-type bipolar transistor 3₄ in the half-selected cell MC4 becomes substantially 0 if the base voltage Vb of the PNP-type bipolar transistor 3₄ is not smaller than Vdd/6.

It is to be noted that a reverse bias is applied to a portion between the base and the emitter of the NPN-type bipolar transistor 2₄, and hence the NPN-type bipolar transistor 2₄ is in the OFF state.

In a situation that the potential in the non-selected bit line BL0 is Vdd/2 in this manner, data can be prevented from being erroneously written into the half-selected cell MC4 connected to the selected word line WL1 when an intensity of the potential in the selected word line WL1 is approximately 20% (approximately Vdd/6) of that of the power supply voltage Vdd.

Further, as shown in FIG. 3A, the potential Vb in the selected word line WL1 is approximately Vdd/6 (=0.2×Vdd) with respect to the selected memory cell MC1, a write current which is equal to or above a reverse threshold current can be supplied to the MTJ element 1₁.

Furthermore, the non-selected cell MC2 adjacent to the selected cell MC1 in the y-direction is connected to the selected bit line BL1. The potential in the selected bit line BL1 is set to the voltage Vdd. Therefore, when the potential in the non-selected word line WL0 connected with the half-selected cell MC2 is set to a value close to the voltage Vdd (<Vdd) in regard to the half-selected cell MC2 connected to the selected bit line BL1, the emitter current of the PNP-type bipolar transistor 3₂ in the half-selected cell MC2 is hardly output. That is, the output current from the PNP-type bipolar transistor 3₂ is sufficiently smaller than the switching threshold current. Further, since the reverse bias is applied to the portion between the emitter and the base of the NPN-type bipolar transistor 2₂ of the half-selected cell MC2, the NPN-type bipolar transistor 2₂ is in the OFF state. Therefore, erroneous writing with respect to the half-selected cell MC2 can be suppressed.

However, when the potential in the non-selected word line WL0 is adjusted to a value close to the potential (the voltage Vdd) in the selected bit line BL1, an operation of the non-selected cell MC3 connected to this non-selected word line WL0 must be considered. The non-selected cell MC3 is adjacent to the half-selected cell MC2 in the x-direction and adjacent to the half-selected cell MC4 in the y-direction.

Therefore, the potential in the non-selected word line WL0 must be set to not only prevent data from being written into the half-selected cell MC2 connected to the selected bit line BL1 but also prevent data from being written into the non-selected cell MC3 that shares the non-selected word line WL0 with the half-selected cell MC2.

The potential in the non-selected bit line BL0 connected with the non-selected cell MC3 is approximately Vdd/2. Therefore, when the potential in the non-selected word line WL0 is changed to the “H” level, i.e., the voltage Vdd, the base voltage Vb increases to be higher than the emitter voltage Ve. In this case, although the PNP-type bipolar transistor 3₃ in the non-selected cell MC3 is in the OFF state, the NPN-type bipolar transistor 2₃ in the non-selected cell MC3 enters the ON state.

To prevent the NPN-type bipolar transistor 2₃ from being turned on, the potential in the non-selected word line WL0 is reduced to be lower than the voltage Vdd.

FIGS. 10A and 10B show a relationship between the base voltage and the emitter current and a relationship between the base voltage and the emitter voltage in the NPN-type bipolar transistor when the potential in the bit line BL is at the “H/2” level (=Vdd/2).

FIG. 10A shows a relationship between the base voltage Vb and the emitter current Ie in the NPN-type bipolar transistor. FIG. 10B shows a relationship between the base voltage Vb and the emitter voltage Ve in the NPN-type bipolar transistor.

In FIG. 10A, an abscissa of a graph is associated with the base voltage Vb, and an ordinate of the graph is associated with the emitter current Ie. In FIG. 10B, an abscissa of a graph is associated with the base voltage Vb, and an ordinate of the graph is associated with the emitter voltage Ve.

As shown in FIGS. 10A and 10B, in a situation that the potential in the non-selected bit line BL0 is approximately Vdd/2, the emitter current Ie of the NPN-type bipolar transistor 3₃ becomes substantially 0 if the base voltage Vb is not greater than Vdd×5/6. Therefore, it is preferable for the potential in the non-selected word line WL0 to be set to a voltage lower than the “H” level (a state “1”), e.g., an intensity of approximately 80% of the power supply voltage Vdd.

As a result, erroneous writing with respect to the non-selected cell MC3 can be suppressed.

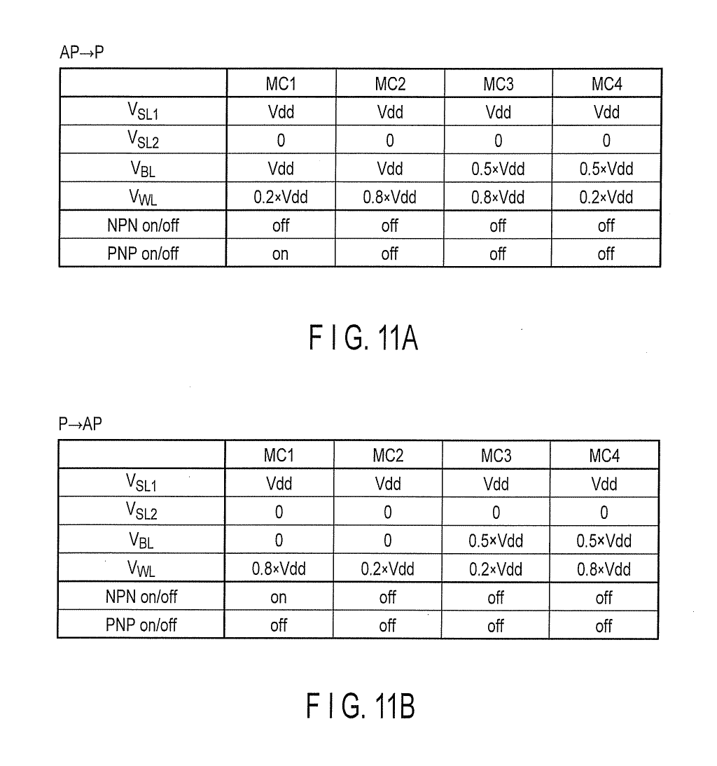

FIG. 11A shows an example of set potentials in the respective control lines based on FIGS. 9A, 9B, 10A, and 10B when the emitter current in the PNP-type bipolar transistor is used as a write current for the MTJ element.

A potential VSL1 in each of the power supply lines SL1 and SL3 is set to the power supply voltage Vdd, and a potential VSL2 in each of the ground lines SL0 and SL2 is set to the ground potential (0 V). These potentials are equally applied to the respective memory cells MC1, MC2, MC3, and MC4.

As shown in FIG. 11A, a potential V_{BL} in the bit line connected to the memory cell MC1 as the selected cell is set to the power supply voltage Vdd, and a potential V_{WL} in the word line connected to the memory cell MC1 is set to approximately 0.2×Vdd. As a result, in the selected cell MC1, the NPN-type bipolar transistor is turned off, and the PNP-type bipolar transistor is turned on.

In the memory cell MC2 connected to the selected bit line BL1 and the non-selected word line WL0, the potential V_{WL} in the non-selected word line WL0 connected to the memory cell MC2 is set to approximately 0.8×Vdd. As a result, the potential V_{BL} in the selected bit line is set to Vdd, and the potential V_{WL} in the non-selected word line is set to 0.8×Vdd, whereby both the bipolar transistors in the half-selected cell MC2 hardly output a current and substantially enter the OFF state.

In the memory cell MC4 connected to the selected word line WL1 and the non-selected bit line BL0, the potential V_{BL} of the non-selected bit line BL0 connected to the half-selected cell MC4 is set to approximately 0.5×Vdd. Since the potential V_{WL} in the word line is set to 0.2×Vdd, both the bipolar transistors in the memory cell MC4 substantially enter the OFF state.

Further, in the memory cell MC3 connected to the non-selected word line WL0 and the non-selected bit line BL0, the potential V_{WL} in the non-selected word line WL0 is set to 0.8×Vdd, and the potential V_{BL} in the non-selected bit line BL0 is set to 0.5×Vdd. Therefore, both the bipolar transistors in the memory cell MC3 substantially enter the OFF state.

As shown in FIG. 11A, setting the potential V_{BL} in the bit line and the potential V_{WL} in the word line in the memory cell array enables writing data into the selected cell by using the current from the PNP-type bipolar transistor, suppressing erroneous writing with respect to the half-selected cell and the non-selected cell.

Furthermore, the output current (the emitter) from the NPN-type bipolar transistor in the memory cell may be used as a write current for the MTJ element in some situations.

In this case, substantially the same situation as that in which the emitter current of the PNP-type bipolar transistor is used as the write current is taken into consideration to set the potentials in the bit line and the word line are set, respectively.

FIG. 11B shows an example of set potentials in the respective control lines based on FIGS. 9 to 10B when the emitter current of the NPN-type bipolar transistor is used as a write current for the MTJ element.

As shown in FIG. 11B, in a selected cell (the memory cell MC1 in this example), the potential V_{BL} in the selected bit line BL is set to 0 V and the potential V_{WL} in the selected word line is set to approximately 0.8×Vdd in such a manner that the NPN-type bipolar transistor is turned on and the PNP-type bipolar transistor is turned off.

In a half-selected cell (the memory cell MC4 in this example) connected to the selected word line, the potential V_{BL} in the non-selected bit line is set to approximately 0.5×Vdd. As a result, both the bipolar transistors 2₄ and 3₄ in the half-selected cell MC4 hardly output a current and substantially enter the OFF state.

In a half-selected cell (the memory cell MC2 in this example) connected to the selected bit line, the potential V_{WL} in the non-selected word line is set to approximately 0.2×Vdd. As a result, both the bipolar transistors 2₂ and 3₂ in the half-selected cell MC2 substantially enter the OFF state.

Moreover, in a non-selected cell (the memory cell MC3 in this example), the potential V_{WL} in the non-selected word line is set to be equal to the potential for the half-selected cell MC2, and the potential V_{BL} in the non-selected bit line is set to be equal to the potential for the half-selected cell MC4. As a result, both the bipolar transistors 3₃ and 2₃ in the non-selected cell MC3 substantially enter the OFF state.

As described above, in the resistance change type memory according to this embodiment, the output current (the emitter current) from each bipolar transistor is used for the write operation with respect to the resistance change type memory element (the MTJ element). Even in the circuit configuration where the current from each bipolar transistor is used as the write current, the selected cell and the non-selected cell in the memory cell array can be driven by controlling the potentials in the bit line and the word line, respectively like the example shown in FIGS. 11A and 11B.

Additionally, when the bipolar transistors are used as constituent elements for the memory cell, the large write current can be supplied to the MTJ element as compared with an example that the write current is supplied to the MTJ element through the field-effect transistor even if miniaturization of the memory cell has advanced.

It is to be noted that the write operation has been exemplified herein to explain the operation of the entire memory cell array, and data can be read from the selected cell in a read operation for the selected cell by setting the set potentials in the bit line and the word line to be smaller than the potentials used in the write operation.

Therefore, according to the resistance change type memory of this embodiment, operation characteristics of the memory can be improved.

### (c) Structure

### (c-1) Structural Example 1

<Structure>

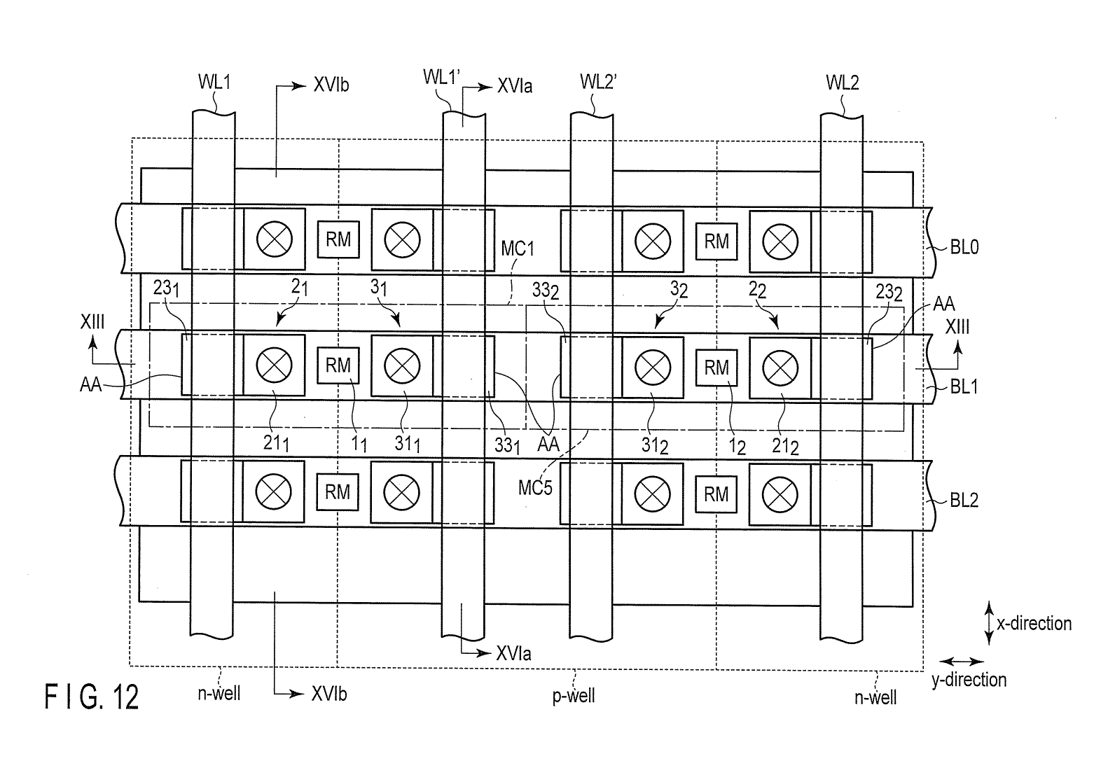

Structural Example 1 of the memory cell array in the resistance change type memory (the MRAM in this example) according to this embodiment will now be described with reference to FIGS. 12, 13, 14A, and 14B. The memory cell array shown in FIG. 12 to FIG. 14B includes memory cells using bipolar transistors having the planar structure.

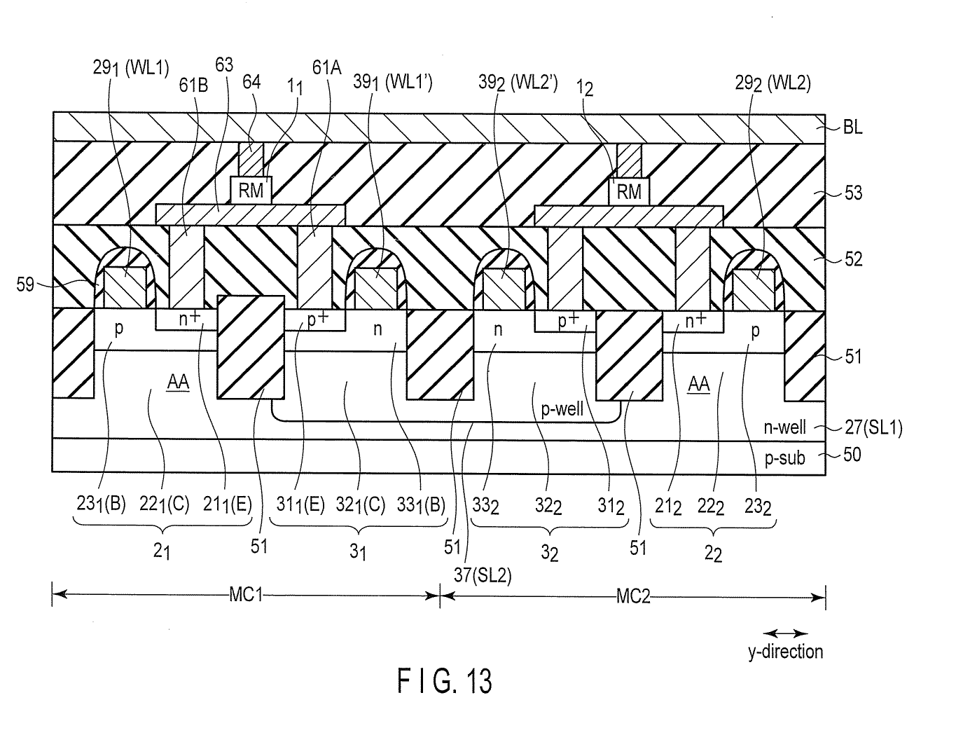

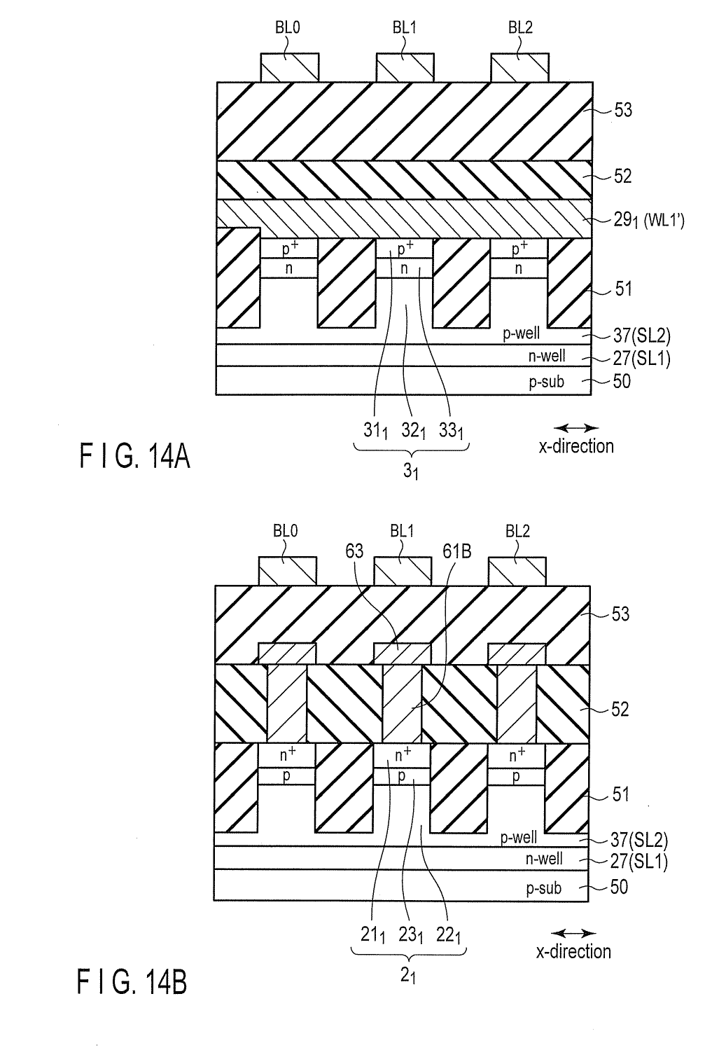

FIG. 12 is a plan view showing a planar structure (a layout) of the memory cell array. FIG. 13 is a cross-sectional view showing a cross section taken along a line XIII-XIII in FIG. 12. FIG. 14A is a cross-sectional view showing a cross section taken along a line XIVa-XIVa in FIG. 12, and FIG. 14B is a cross-sectional view showing a cross section taken along a line XIVb-XIVb in FIG. 12.

It is to be noted that a structure of one memory cell in a memory cell array is substantially the same as that described with reference to FIGS. 6A and 6B. Therefore, here, detailed description of a structure of a memory cell will be given as required.

As shown in FIGS. 12 to 14B, memory cells MC adjacent to each other in the x-direction are electrically separated from each other by an isolation insulating film. Further, memory cells MC adjacent to each other in the y-direction are electrically separated from each other by the isolation insulating film.

As described above, the memory cells adjacent to each other in the y-direction are laid out on a semiconductor substrate 50 to have a line-symmetric relationship (a mirror image relationship) with a power supply line SL1 or a ground line SL2 being used as an axis of symmetry.

In the example shown in FIGS. 12 to 14B, two PNP-type bipolar transistors 3₁ and 3₂ are adjacent to each other in two memory cells adjacent to each other in the y-direction. Incidentally, the two memory cells adjacent to each other in the y-direction in the memory cell array may be arranged in the memory cell array in such a manner that two NPN-type bipolar transistors 2 are adjacent to each other.

For example, p-well regions 32₁ and 32₂ as collector layers of the PNP-type bipolar transistors 3₁ and 3₂ are also used as the ground line SL2. Therefore, a p-well region 37 is provided in a semiconductor substrate (an n-well region 27) to cut across a region where the two PNP-type bipolar transistors of neighboring memory cells are formed without being divided by the isolation insulating film. Furthermore, the p-well region 37 extends in, e.g., the x-direction. As a result, the p-well region 37 is shared by memory cells (PNP-type bipolar transistor) that share the ground line SL2.

For example, the n-well region 27 is continuous in the substrate 50 without being divided by the isolation insulating film. The n-well region 27 is used as collector layers 22₁ and 22₂ of the NPN-type bipolar transistors and also used as the power supply line SL1.

Here, a power supply voltage Vdd is applied to the n-well region 27, and a ground potential Vss is applied to the p-well region 37. Therefore, a reverse bias is applied to a pn junction of the two well regions 27 and 39.

The n-type collector layer 22 and the p-type collector layer 32 are also used as the high-potential (Vdd) side power supply line SL1 and a low-potential (Vss) side ground line SL2 in a triple well structure.

In this case, considering resistance values of well regions 22 and 32 (which will be referred to as well resistance), since an influence of a voltage drop due to the well resistance is remarkable, it is preferable to shunt each power supply and the well regions 22 and 32 at predetermined intervals by using metal interconnects and a contacts. As a result, a sufficient voltage/current can be supplied to the memory cells MC, thus stabilizing operations of the memory cells.

As shown in FIG. 14A, respective interconnects 29₁, 29₂, 39₁, and 39₂ extend on p-type base layers 23₁ and 23₂, n-type base layers 33₁ and 33₂, and the isolation insulating film 51 along the x-direction. The respective interconnects 29₁, 29₂, 39₁, and 39₂ are shared by the memory cells (the bipolar transistors). The two interconnects 29₁ and 29₂ or 39₁ and 39₂ form one pair of word lines, and these interconnects 29₁, 29₂, 39₁, and 39₂ substantially function as word lines WL1, WL1′, WL2, and WL2′.

As shown in FIG. 14B, a contact 61B and an intermediate interconnect 63 on an n⁺-type emitter layer 21₁ are electrically separated from each other in accordance with each memory cell. A contact 61A and the intermediate interconnect 63 on the n⁺-type emitter layer 21₁ are also electrically separated from each other in accordance with each memory cell.

A minimum processing dimension (which will be referred to as a half pitch) of a member (e.g., the isolation insulating film) formed in the semiconductor region is determined as F. Since the two memory cells MC adjacent to each other share an isolation region, a dimension of the isolation region between the memory cells adjacent to each other is determined to be 0.5 F per memory cell. Moreover, a dimension of a bipolar transistor forming region in the y-direction is, e.g., 2 F. That is, in one bipolar transistor, a sum of a dimension of the emitter layer and a dimension of the base layer in the y-direction is 2 F. A dimension of the bipolar transistor forming region in the x-direction is, e.g., F. In this case, in the memory cell MC including the planar type bipolar transistors 2 and 3, a cell size of one memory cell is 12 F².

<Manufacturing Method>

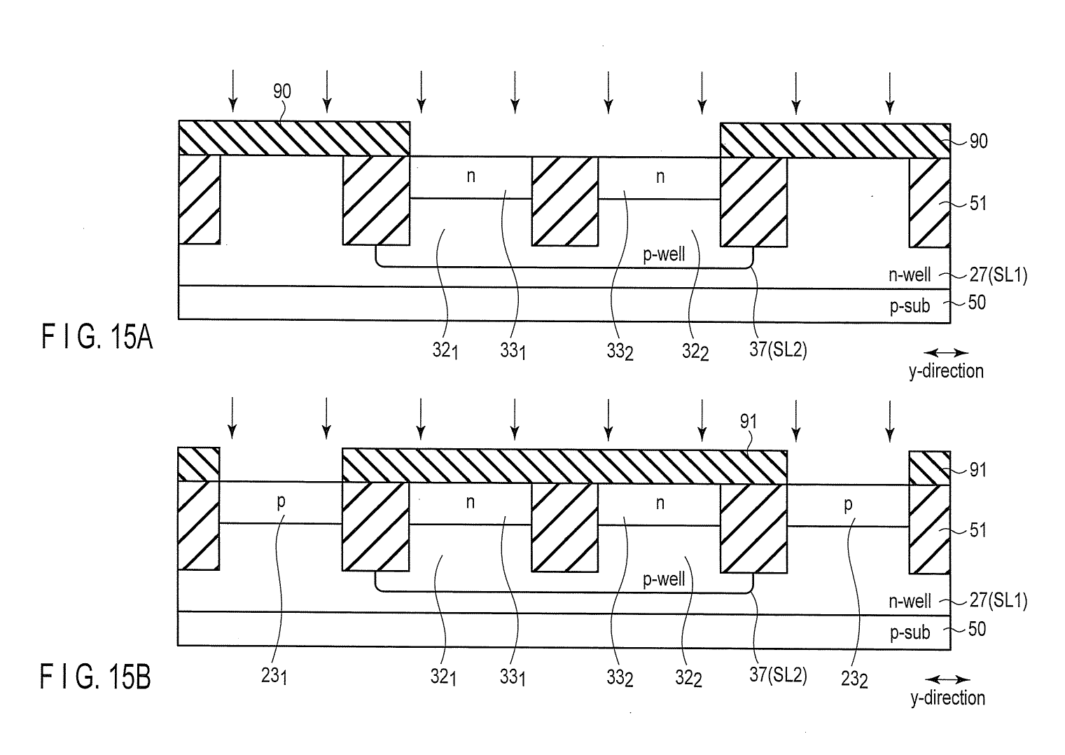

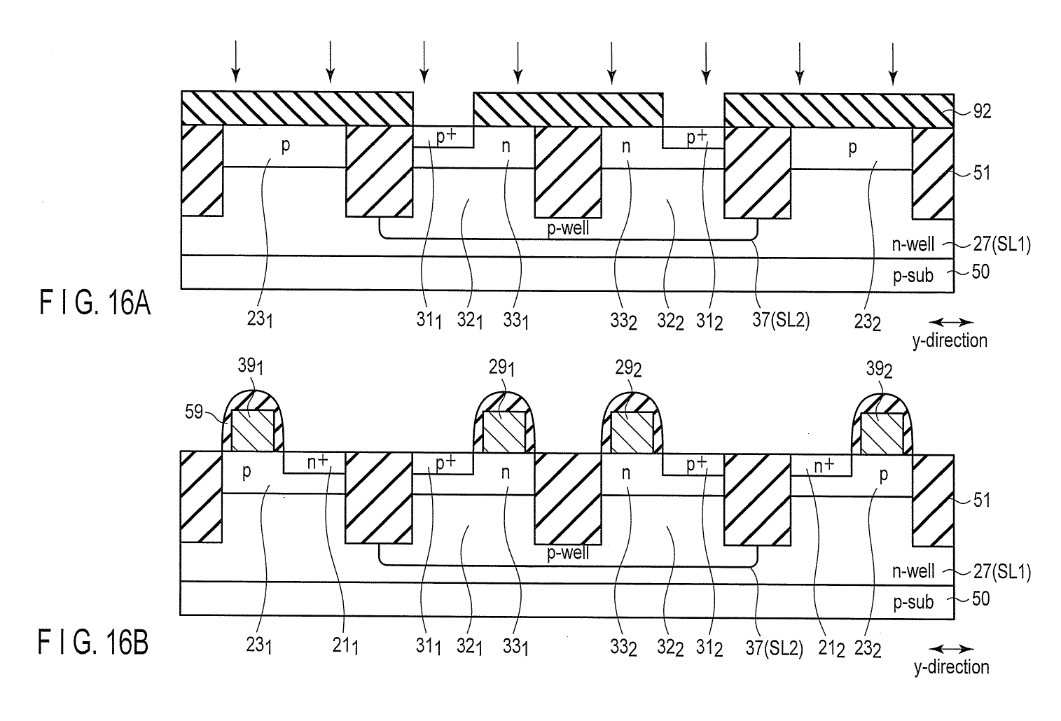

A first manufacturing method of the resistance change type memory according to this embodiment will now be described with reference to FIGS. 15A, 15B, 16A, and 16B. In the first manufacturing method, a manufacturing method of a resistance change type memory in which bipolar transistors having the planar structure are used in a memory cell will be explained.

FIGS. 15A, 15B, 16A, and 16B show manufacturing steps in a cross section along the y-direction of a memory cell array.

As shown in FIG. 15A, an n-type well region 27 and a p-well region 37 are formed in a p-type semiconductor substrate 50. Trenches are formed in the p-type semiconductor substrate 50. An isolation insulating film 51 is buried in each formed trench. A dimension of the isolation insulating film 51 in the y-direction is, e.g., F (a half pitch).

In the n-well region 27, a portion in an NPN-type bipolar transistor forming region is used as a collector layer of an NPN-type bipolar transistor. The n-well region 27 is also used as a power supply line SL1. In the p-well region 37, a portion in a PNP-type bipolar transistor forming region is used as a collector of a PNP-type bipolar transistor. Additionally, the p-well region 37 is also used as a ground line.

A resist is applied to an upper surface of the semiconductor substrate 50. Further, the resist is patterned by the photolithography technology to form a resist mask 90 having an opening portion. The opening portion of the resist mask 90 is formed on the PNP-type bipolar transistor forming region. After the opening portion is formed, n-type impurity layers 33₁ and 33₂ are formed in p-type well regions 32₁ and 32₂ by ion implantation. The n-type impurity layers 33₁ and 33₂ are used as base layers of PNP-type bipolar transistors.

For example, as shown in FIG. 15A, in light of a process, it is preferable for the PNP-type bipolar transistor forming regions to be adjacent to each other to sandwich the isolation insulating film between two memory cells MC adjacent to each other in the y-direction. Furthermore, it is also preferable for the NPN-type bipolar transistor forming regions to be adjacent to each other to sandwich the isolation insulating film therebetween.

Then, the resist mask 90 is delaminated.

As shown in FIG. 15B, a resist mask 91 is formed on the semiconductor substrate 50 by using the photolithography technology. Opening portions are formed in the resist mask 91 so that the NPN-type bipolar transistor forming regions (n-well regions) are exposed. The resist mask 91 covers the surface of the PNP-type bipolar transistor forming region.

Based on ion implantation, p-type impurity layers 23₁ and 23₂ are formed in the n-well regions 22 of the NPN-type bipolar transistor forming regions. The p-type impurity layers 23₁ and 23₂ are used as base layers of the NPN-type bipolar transistors.

After the p-type impurity layers 23₁ and 23₂ are formed, the resist mask 91 is delaminated.

As shown in FIG. 16A, a resist mask 92 is formed on the semiconductor substrate 50. Opening portions are formed in the resist mask 92 so that surfaces of regions where emitters are formed (n-type impurity layers 33₁ and 33₂) in the PNP-type bipolar transistor forming regions can be partially exposed.

Moreover, based on the ion implantation, p⁺-type impurity layers 31₁ and 31₂ as emitters of the PNP-type bipolar transistors are formed in the n-type impurity layers 33₁ and 33₂. As a result, the PNP-type bipolar transistors are formed in the semiconductor substrate 50.

After the p⁺-type impurity layers 31₁ and 31₂ are formed, the resist mask 92 is delaminated.

Thereafter, a resist mask is formed on the semiconductor substrate 50 by the same technique. Opening portions are formed in this resist mask in such a manner that surfaces of regions where emitters are formed (the p-type impurity layers 23₁ and 23₂) are exposed in the NPN-type bipolar transistor forming region. Further, the resist mask is used as a mask to perform the ion implantation.

Then, as shown in FIG. 16B, n⁺-type impurity layers 21₁ and 21₂ as emitters of the NPN-type bipolar transistors are formed in the p-type impurity layers 23₁ and 23₂. As a result, the NPN-type bipolar transistors are formed in the semiconductor substrate 50. Each of dimensions of the emitter layers 31₁, 31₂, 21₁, and 21₂ in the y-direction is, e.g., F.

Then, for example, polysilicon is deposited on the surface of the semiconductor substrate 50 by using, e.g., a CVD (Chemical Vapor Deposition) method. Further, the polysilicon is processed to extend in, e.g., the x-direction by using a photolithography technology and an RIE (Reactive Ion Etching) method. As a result, interconnects 29₁, 29₂, 39₁, and 39₂ as word lines are formed on the base layers 23₁, 23₂, 33₁, and 33₂ of the NPN-type/PNP-type bipolar transistors.

It is to be noted that the interconnects 29₁, 29₂, 39₁, and 39₂ may be formed by using a metal. In this case, the metal is deposited on the semiconductor substrate 50 by using a sputtering method.

To prevent the interconnects 29₁, 29₂, 39₁, and 39₂ from coming into contact with the emitter layers 21₁, 21₂, 31₁, and 31₂, it is preferable for dimensions of the interconnects 29₁, 29₂, 39₁, and 39₂ to be not greater than dimensions of upper surfaces of the base layers 23₁, 23₂, 33₁, 33₂. Therefore, forming the interconnects 29₁, 29₂, 39₁, and 39₂ by using a slimming technology or a sidewall transfer processing technology is preferable.

After the interconnects 29₁, 29₂, 39₁, and 39₂ are formed, an insulating film (e.g., silicon nitride) is deposited on the semiconductor substrate 50 by, e.g., the CVD method. This insulating film is etched back based on anisotropic etching. Then, a sidewall insulating film 59 selectively remains on upper surfaces and side surfaces of the interconnects 29₁, 29₂, 39₁, and 39₂.

Subsequently, as shown in FIGS. 13, 14A, and 14B, a first interlayer insulating film 52 is deposited on the interconnects 29₁, 29₂, 39₁, and 39₂ and the semiconductor substrate 50 based on the CVD method.

Contact holes are formed in the interlayer insulating film 52 so that surfaces of the n⁺-type/p⁺-type impurity layers 21₁, 21₂, 31₁, and 31₂ as emitters are exposed. Contact plugs 61A and 61B are buried in the contact holes.

A conductive film is deposited on the interlayer insulating film 52 and the contact plugs 61A and 61B by, e.g., the sputtering method. The conductive film is processed in such a manner that the emitter layers of the two bipolar transistors in each memory cell are connected to each other. As a result, intermediate interconnects 63 that connect the n⁺-type emitter layers 21₁ and 21₂ of the NPN-type bipolar transistors with the p⁺-type emitters 31₁ and 31₂ of the PNP-type bipolar transistors are formed.

Constituent members of resistance change type memory elements 1₁ and 1₂ are sequentially deposited on the intermediate interconnects 63. For example, when each of the resistance change type memory elements 1₁ and 1₂ is an MTJ element, a lower electrode, a first magnetic layer, a tunnel barrier layer, a second magnetic layer, and an upper electrode are sequentially deposited on each intermediate interconnect 63 by, e.g., the sputtering method. One of the first and second magnetic layers functions as a reference layer and the other serves as a recording layer in accordance with a material or a circuit configuration adopted for the MTJ element.

Further, a second interlayer insulating film 53 is deposited on the first interlayer insulating film 52 to cover the MTJ elements 1₁ and 1₂. Contact holes are formed in the interlayer insulating film 53 to expose the upper electrodes of the MTJ elements 1₁ and 1₂, and via plugs 64 are buried in the contact holes.

Furthermore, a metal film is deposited on the second interlayer insulating film 53 by, e.g., the sputtering method. The metal film is processed into a predetermined shape, thereby forming a bit line BL extending in the y-direction.

Based on the above-described steps, the resistance change type memory according to this embodiment is formed.

When the bipolar transistors having the planar structure are used for the memory cells, the memory cell array can be formed by a relatively easy process, thus reducing a manufacturing cost of the resistance change type memory.

As described above, according to the first manufacturing method of the resistance change type memory of this embodiment, the resistance change type memory having improved characteristics can be provided.

### (c-2) Structural Example 2

<Structure>

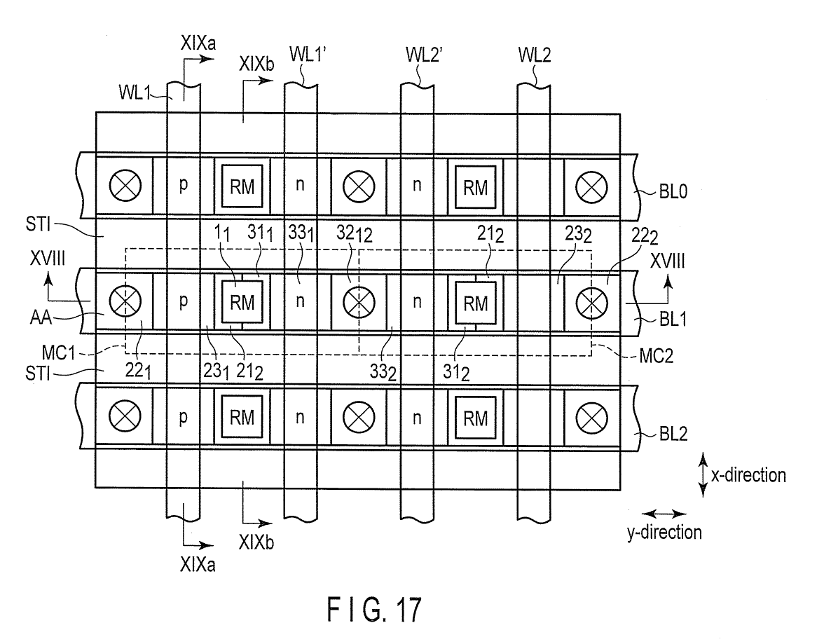

Structural Example 2 of the memory cell array of the resistance change type memory (the MRAM) according to this embodiment will now be described with reference to FIGS. 17, 18, 19A, and 19B.

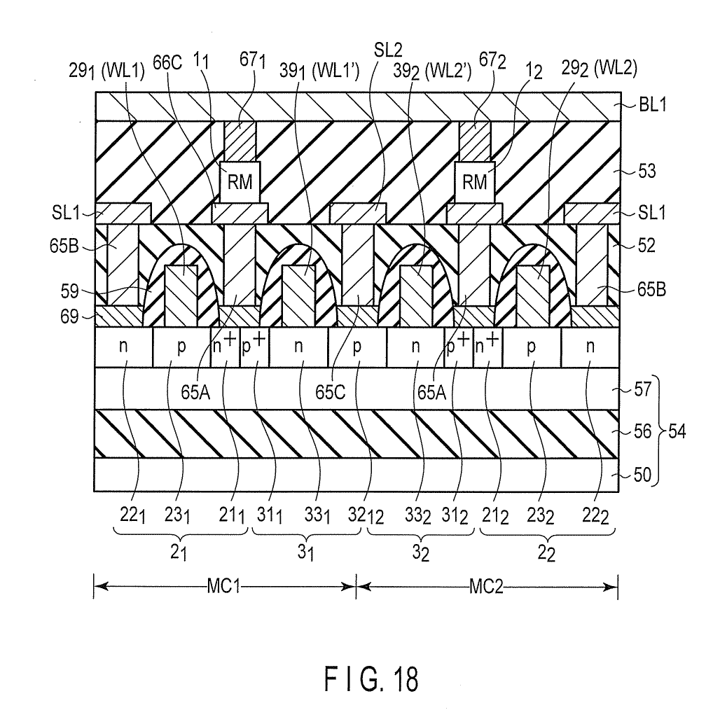

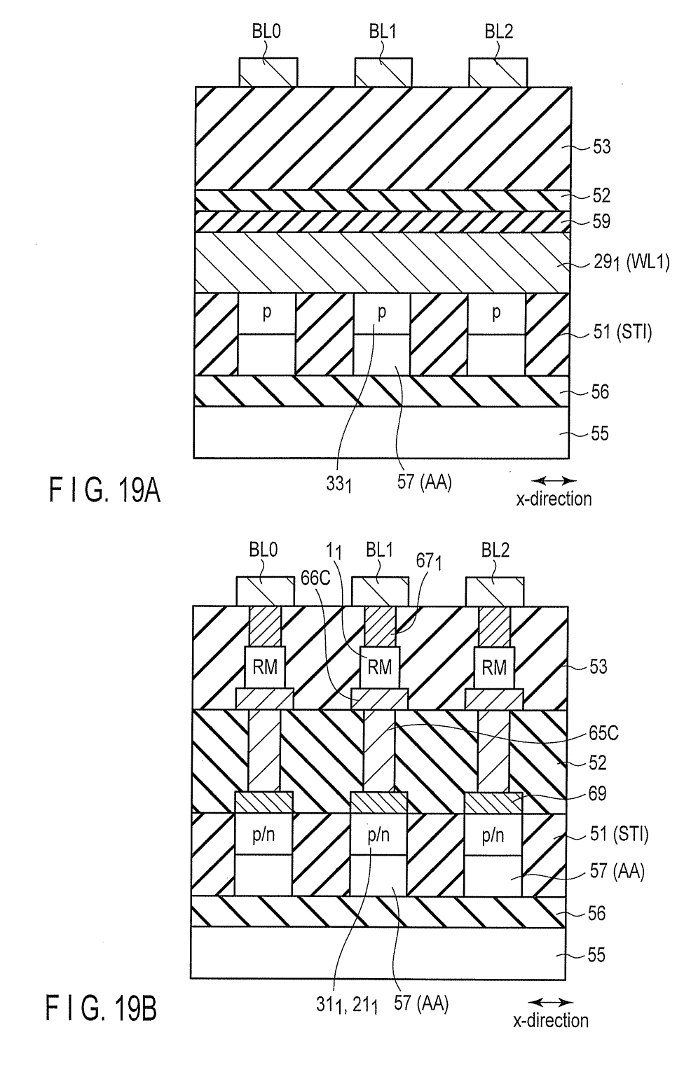

FIG. 17 is a plan view showing a planar structure (a layout) of the memory cell array. FIG. 18 is a cross-sectional view showing a cross section taken along a line XVIII-XVIII in FIG. 17. FIG. 19A is a cross-sectional view showing a cross section taken along a line XIXa-XIXa in FIG. 17, and FIG. 19B is a cross-sectional view showing a cross section taken along a line XIXb-XIXb in FIG. 17.

The memory cell array shown in FIGS. 17 to 19B includes memory cells using bipolar transistors having a lateral structure.

It is to be noted that a structure of one memory cell in the memory cell array in FIGS. 17 to 19B is substantially the same as the structure described in conjunction with FIGS. 7A and 7B. Therefore, here, detailed description of the structure of the memory cell will be given as required.

The memory cell using the bipolar transistors having the lateral structure is not a structure supplying a current to an MTJ element through well regions. Therefore, in the memory cell using the bipolar transistors having the lateral structure, an isolation region does not have to be provided between memory cells adjacent to each other in the y-direction. Therefore, a size of the memory cell can be reduced. In the memory cell array formed of the memory cells using the bipolar transistors having the lateral structure, an SOI layer 57 of an intrinsic semiconductor is used as each bipolar transistor forming region to electrically separate impurity layers adjacent to each other in the y-direction, thereby reducing a leak current between the memory cells.

The memory cells aligned in the y-direction are provided in a common active region AA. Therefore, the active region AA is continuous in the y-direction.

As shown in FIGS. 19A and 19B, the two active regions AA adjacent to each other in the x-direction are electrically separated from each other by each isolation insulating film 51. The isolation insulating film 51 extends in the y-direction between the two active regions AA adjacent to each other in the x-direction. In the memory cell array, one active region AA has a layout sandwiched between two isolation regions in the x-direction. Assuming that the active regions AA form a line pattern and the isolation regions form a space pattern, a layout of a substrate in the memory cell array is a line-and-space layout. A dimension of the active region AA in the x-direction is, e.g., F, and a dimension of the isolation regions in the x-direction is, e.g., F.

Each of collector layers 22₁, 22₂, and 32₁₂ and base layers 23₁, 23₂, 33₁, and 33₂ has a dimension F.

Silicide layers 69 are provided on the collector layers 22₁, 22₂, and 32₁₂ and emitter layers 21₁, 21₂, 31₁, and 31₂. Contact plugs 65A, 65B, and 65C are provided on the silicide layers 69, respectively. The collector layers 22₁, 22₂, and 32₁₂ and the emitter layers 21₁, 21₂, 31₁, and 31₂ are connected to a power supply line SL1 and a ground line SL2 through the silicide layers 69 and the contact plugs 65A, 65B and 65C, respectively.

An interconnect above each of the n-type collector layers 22₁ and 22₂ is the power supply line SL1. An interconnect above the p-type collector layer 32₁₂ is the ground line SL2. The collector layers 22₁, 22₂, and 32₁₂, the contact plugs 65A, 65B, and 65C, and the interconnects SL1 and SL2 are shared by the memory cells adjacent to each other in the y-direction. The contact plugs 65A, 65B, and 65C are arranged between the sidewall insulating films 59 adjacent to each other in the y-direction.

MTJ elements 1₁ and 1₂ are provided above the emitter layers 21₁, 21₂, 31₁, and 31₂. As described above, the emitter layers 21₁, 21₂, 31₁, and 31₂ are formed in the SOI layer 57 so that the two impurity layers which are of the n⁺-type and the p⁺-type can fall within the half pitch dimension F.

It is to be noted that an intrinsic semiconductor layer may be interposed between each of the n⁺-type emitter layers 21₁ and 21₂ and each of the pt-type emitter layers 31₁ and 31₂.

In the memory cell array using the bipolar transistors having the lateral structure, the collector layers can be shared by the memory cells adjacent to each other in the y-direction, and each isolation region between the memory cells adjacent to each other in the y-direction can be eliminated. Moreover, in the bipolar transistors having the lateral structure according to this embodiment, the two emitter layers can be formed within the half pitch (F).

Therefore, a cell size of the memory cell according to Structural Example 2 can be reduced to be smaller than that in Structural Example 1. The cell size of the memory cell according to Structural Example 2 is, e.g., 8 F².

<Manufacturing Method>

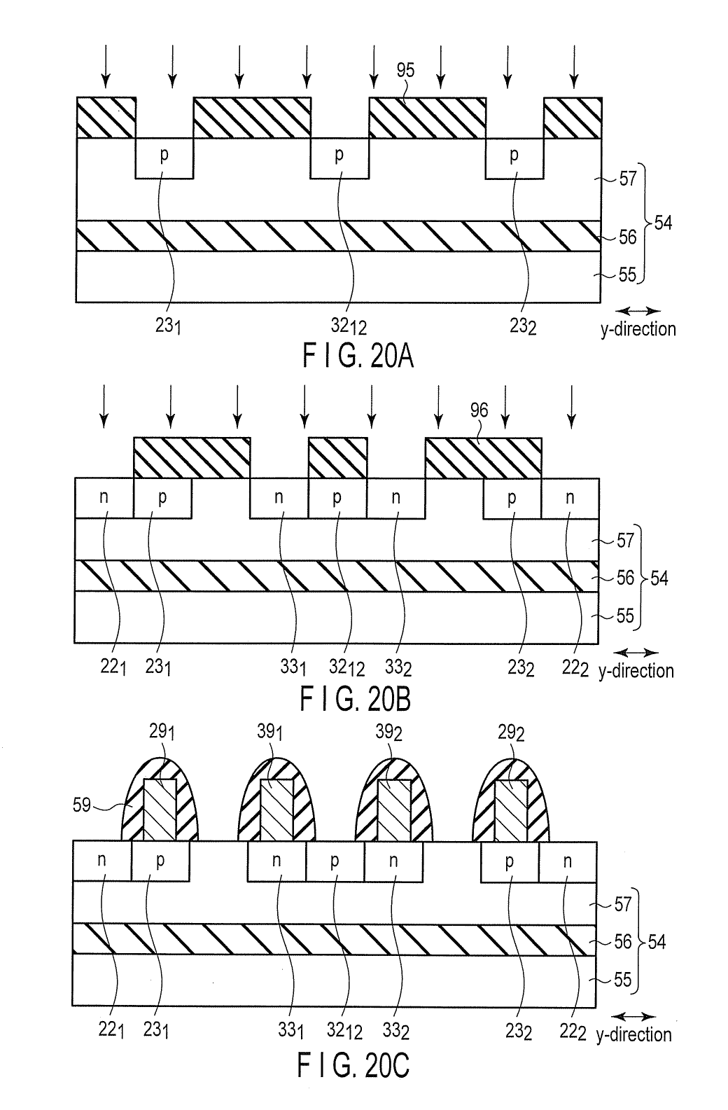

A second manufacturing method of the resistance change type memory according to this embodiment will now be described with reference to FIGS. 20A, 20B, 20C, 21A, 21B, 22A and 22B. In the second manufacturing method, a manufacturing method of the resistance change type memory using the bipolar transistors having the lateral structure for the memory cell will be explained.

FIGS. 20A to 22B show cross sections of the memory cell array in respective manufacturing steps taken along the y-direction.

As shown in FIG. 20A, a resist mask 95 is formed on an SOI layer (e.g., an intrinsic semiconductor layer) 57 on an SOI substrate 54.

For example, p-type impurity layers 23₁, 23₁₂, and 23₂ are formed in the SOI layer 57 based on the ion implantation method. As a result, a base layer of an NPN-type bipolar transistor and a collector layer of a PNP-type bipolar transistor are formed. Each of p-type impurity layers 23₁, 23₁₂, and 23₂ has a dimension of F (a half pitch).

After the resist mask 95 is delaminated, as shown in FIG. 20B, a new resist mask 96 is formed. Opening portions are formed in the resist mask 96, and a region where a collector layer of the NPN-type bipolar transistor is formed and a region where a base layer of the PNP-type bipolar transistor is formed are exposed. The resist mask 96 covers upper surfaces of the p-type impurity layers 23₁, 23₁₂, and 23₂ and an upper surface of the region where the emitter layer is formed.

N-type impurity layers 22₁, 22₂, 33₁, and 33₂ are formed in the SOI layer 57 based on the ion implantation. Each of the n-type impurity layers 22₁, 22₂, 33₁, and 33₂ has the dimension of F.

Incidentally, conversely to the steps depicted in FIGS. 20A and 20B, the p-type impurity layers 23₁, 23₂, and 32₁₂ may be formed after the n-type impurity layers 22₁, 22₂, 33₁, and 33₂ are formed.

As shown in FIG. 20C, a conductive layer (e.g., a polysilicon layer) is deposited on the SOI layer 57 by the CVD method. The conductive layer is deposited before forming, e.g., the emitter layers of the bipolar transistors.

The conductive layer is formed into a predetermined shape by using the photolithography technology and the RIE method. As a result, interconnects (word lines) 29₁, 29₂, 39₁, and 39₂ are formed on the p-type/n-type impurity layers 23₁, 23₂, 33₁, and 33₂ as the base layers.

An insulating film (e.g., a silicon nitride) is deposited to cover the interconnects 29₁, 29₂, 39₁, and 39₂ and the SOI layer 57, and this insulating film is etched back. As a result, a sidewall insulating film 59 is formed on side surfaces and upper surfaces of the interconnects 29₁, 29₂, 39₁, and 39₂. On the other hand, the insulating film is removed from an upper surface of the SOI layer 57, whereby the upper surface of the SOI layer 57 is exposed.

In this case, before forming the emitter layers of the bipolar transistors, the interconnects (the word lines) are formed on the base layers 23₁, 23₂, 33₁, and 33₂ of the respective bipolar transistors.

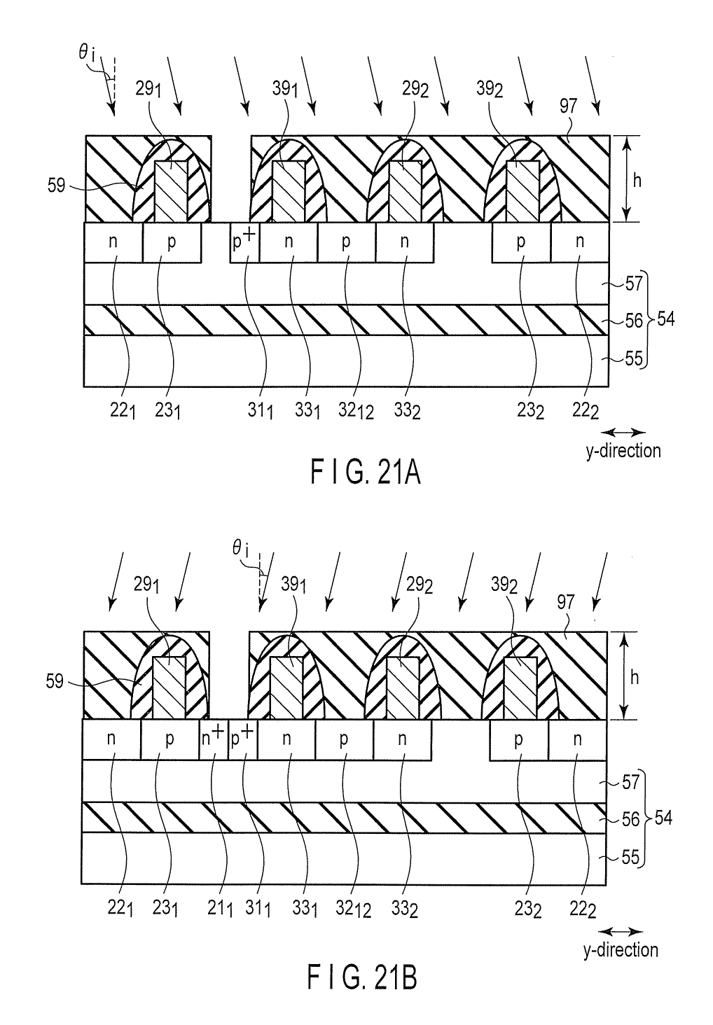

As shown in FIG. 21A, a resist mask 97 is formed to cover the SOI layer 57 and the interconnects 29₁, 29₂, 39₁, and 39₂. For example, the resist mask 97 has a film thickness h. An opening portion is formed in the resist mask 97 to expose the region where the emitter layer is formed.

As shown in FIG. 21A, for example, a p-type impurity layer 31₁ as the emitter layer is formed in the SOI layer 57 to be adjacent to the n-type impurity layer (the base layer) 331.

Here, the ion implantation having an ion incidence direction set to an oblique direction with respect to the substrate surface is carried out. An incidence angle θᵢ of ions (which will be referred to as an ion incidence angle) is an oblique direction with respect to a vertical direction of the substrate surface. The ion incidence angle θᵢ is set based on the vertical direction of the substrate surface of the incidence direction of ions.

Ions are not added to the inside of the SOI layer 57 that is hidden behind the resist mask 97 and the interconnect 29₁ with respect to the incidence direction of ions in the ion implantation is carried out from the oblique direction in this manner. Therefore, in the region exposed by the opening portion, the p-type impurity layer 31₁ as the emitter layer is formed with a dimension associated with the film thickness (a height) of the resist mask 97 and the ion incidence angle θᵢ in a straight line of the incidence direction of ions.

As shown in FIG. 21B, the incidence direction of ions is set to the opposite direction, and the ion implantation is performed from the oblique direction. The incidence angle θᵢ of ions is set in such a manner that the emitter layer (the p-type impurity layer) 31₁ formed at the step of FIG. 21A is hidden behind the resist mask 97 and the interconnect 39₁ with respect to the incidence direction of ions. As a result, an n-type impurity layer 21₁ is formed between the base layer 23₁ of the NPN-type bipolar transistor and the emitter layer 31₁ of the PNP-type bipolar transistor.

As shown in FIGS. 21A and 21B, when the height h of the resist mask 97 (or the interconnects 29₁ and 39₁) and the ion incidence angle θᵢ are appropriately set, the two impurity layers 21₁ and 31₁ are formed to fall within the predetermined dimension (the half pitch) F. That is, the impurity layers 21₁ and 31₁ each having the dimension of substantially F/2 can be formed in the region having the dimension F in the SOI layer 57 at the steps shown in FIGS. 21A and 21B.

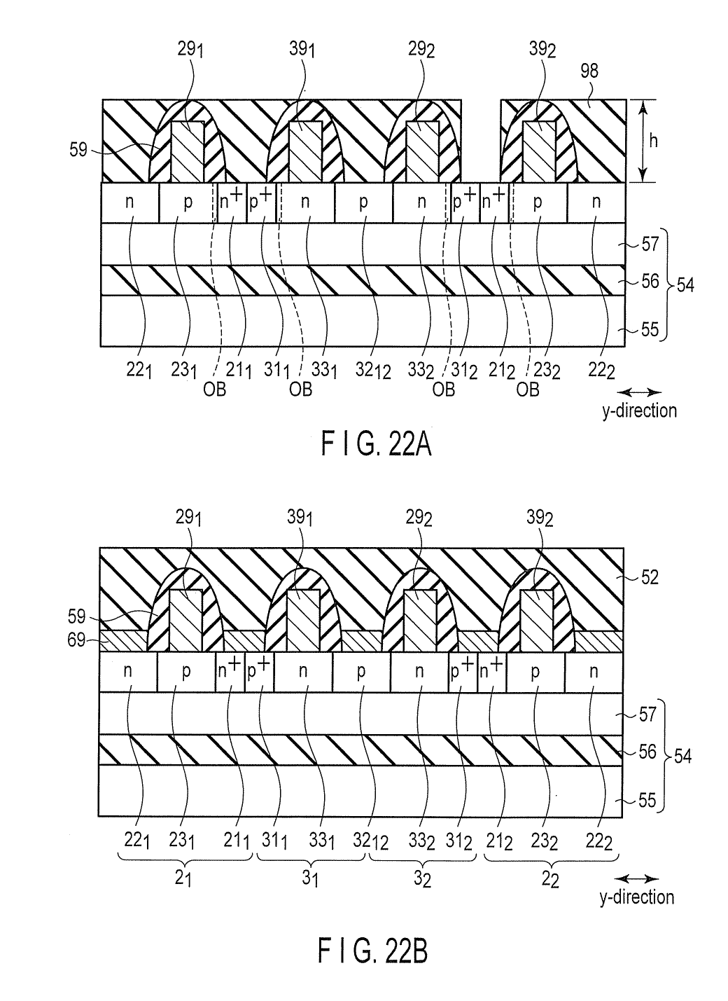

As described above, since the memory cells adjacent to each other are laid out to have a mirror image relationship, there is a region where the arrangement of the n-type emitter layers and the p-type emitter layers with respect to the extending direction of the active region are reversed for each memory cell as shown in FIG. 22A in accordance with a layout of the memory cells. Therefore, the ion implantation is carried out from the oblique directions in such a manner that the incidence direction of p-type ions and the incidence direction of n-type ions are opposite to each other as shown in FIGS. 21A and 21B. Consequently, as depicted in FIG. 22A, two impurity layers 21₂ and 31₂ are formed within the half pitch like the impurity layers formed at the steps shown in FIGS. 21A and 21B.

Here, when the ion implantation is carried out in such a manner that portions OB where the emitter layers 21₁, 31₁, 21₂, and 31₂ overlap the base layers 23₁, 23₂, 33₁, and 33₂ are generated, dimensions of the base layers 23₁, 23₂, 33₁, and 33₂ in a direction parallel to the substrate surface can be reduced to be smaller than the half pitch. When the dimensions of the base layers 23₁, 23₂, 33₁, and 33₂ are reduced, operation characteristics of the bipolar transistors can be improved.

An intrinsic semiconductor layer (the SOI layer 57) may remain between the n⁺-type impurity layers 21₁ and 21₂ and the p⁺-type impurity layers 31₁ and 31₂.

It is to be noted that the interconnects 29₁, 29₂, 39₁, and 39₂ may be formed after the emitter layers 21₁, 31₁, 31₂, and 31₂ are formed by using the ion implantation in the oblique directions and the resist mask having the predetermined film thickness.

After forming the emitter layers 21₁, 31₁, 21₂, and 31₂, the resist mask is removed.

As shown in FIG. 22B, a silicide layer 69 is formed on the exposed SOI layer 57. For example, the sidewall insulating film 59 formed on the side surfaces of the interconnects 29₁, 29₂, 39₁, and 39₂ prevents the impurity layers from being short-circuited by the silicide layer.

Then, an interlayer insulating film 52 is deposited on the SOI substrate 50 by, e.g., the CVD method. Further, contact plugs 65A, 65B, and 65C, resistance change type memory elements 11 and 12, and interconnects 63, SL1, SL2, and BL are sequentially formed at the same steps as those in the first manufacturing method. Each contact plug 65A is formed on the silicide layer 69 to cut across the two emitter layers 21₁ and 31₁ or 21₂ and 31₂.

Consequently, as shown in FIGS. 18, 19A, and 19B, the resistance change type memory according to this embodiment is fabricated. The constituent members of the bipolar transistors can be formed by the ion implantation even though the bipolar transistors having the lateral structure are used in the memory cells in this manner.

When the bipolar transistors having the lateral structure are used in the memory cells, it is possible to provide the resistance change type memory including the memory cell transistors having a smaller cell size than that in the example where the bipolar transistors having the planar structure are used.

As described above, according to the second manufacturing method of the resistance change type memory of this embodiment, the resistance change type memory having improved characteristics can be provided.

### (3) Modification

In the resistance change type memory, the MRAM or the STT-RAM (a magnetic memory) is exemplified. A magnetoresistive element (magnetoresistive effect element) is used as the resistance change type memory element 1 in the memory cell.

However, the resistance change type memory according to this embodiment may be a memory using a variable resistive element as a memory element (e.g., an ReRAM), a phase-change memory using a phase-change element as a memory element (e.g., a PCRAM), or an ion memory.

A basic configuration of the resistance change type memory element (the variable resistive element) 1 used in an ReRAM is shown.

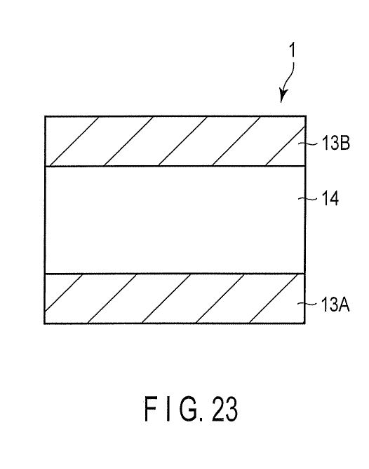

As shown in FIG. 23, the variable resistive element 1 as a memory element includes two electrodes 13A and 13B and a resistance change film 14 sandwiched between the electrodes 13A and 13B.

The resistance change film 14 has properties (characteristics) that a resistance value thereof varies when a voltage or a current is supplied. For example, the resistance change film 14 is formed of, e.g., a transition metal oxide film or a perovskite-type metal oxide.

For example, the transition metal oxide film is exemplified by NiOₓ, TiOₓ, or CuₓO (e.g., 1≦x≦2), and the perovskite-type metal oxide is exemplified by PCMO (Pr_{0.7}Ca_{0.3}MnO₃), Nb-added SrTi(Zr)O₃, or Cr-added SrTi(Zr)O₃.

The properties that the resistance value of the resistance change film 14 varies appear or are stably obtained are based on, e.g., combinations of the resistance change film 14 and the electrodes 13A and 13B. Therefore, it is preferable to appropriately select a material for the electrodes 13A and 13B in accordance with a material for the resistance change film 14. The electrodes 13A and 13B are used as terminals of the memory element 1.

A resistance state of the resistance change type memory element 1 varies depending on an operation mode called a bipolar type or an operation mode called a unipolar type.

In regard to the resistance change type memory element which is of the bipolar type, the resistance state of the resistance change type memory element changes depending on a polarity of a voltage applied to a portion between terminals. In regard to the resistance change type memory element which is of the unipolar type, the resistance state of the resistance change type memory element changes depending on an intensity of a program voltage applied to a portion between terminals.

For example, a resistance value of the resistance change type memory element which is of the bipolar type changes based on the movement of ions (a change in concentration profile) in the resistance change film 14. For example, a resistance value of the resistance change type memory element which is of the unipolar type changes based on generation or annihilation (including partial annihilation) of a fine current path (a filament) in the resistance change film 14.

Whether the resistance change type memory element is of the unipolar type or the bipolar type is mainly dependent on a material of the resistance change film 14.

When a predetermined program voltage (or current) is applied to the portion between the terminals, a resistance state of the resistance change type memory element (the variable resistance element) is reversibly changed from a high-resistance state to a low-resistance state or from the low-resistance state to the high-resistance state irrespective of whether the resistance change type memory element is of the bipolar type or the unipolar type. Further, the changed resistance state of the resistance change type memory element is substantially nonvolatile until the predetermined program voltage is applied.

When the resistance change type memory element 1 is the resistance change type memory element which is of the bipolar type, polarities of voltages applied to the electrodes 13A and 13B are reversed depending on a situation that the resistance state of the element is changed to the low-resistance state (a program state, writing data “0”) and a situation that the resistance state of the same is changed to the high-resistance state (an erased state, writing data “1”).

In the resistance change type memory element which is of the bipolar type, when the electrode 13A of the memory element 1 is set to the high-potential side and the electrode 13B of the memory element 1 is set to the low-potential side, a bias is applied along a direction extending from the electrode 13A to the electrode 13B. For example, the resistance state of the resistance change type memory element 1 changes from the high-resistance state to the low-resistance state. However, in this voltage setting state, if the resistance state of the low-resistance change type memory element 1 is the low-resistance state, the resistance state of the resistance change type memory element 1 does not change. On the other hand, when the electrode 13B of the memory element 1 is set to the high-potential side and the electrode 13A of the memory element 1 is set to the low-potential side, the bias is applied along a direction extending from the electrode 13B to the electrode 13A. In this case, as opposed to the case that the electrode 13A is set to the high-potential side, the resistance state of the resistance change type memory element 1 changes from the low-resistance state to the high-resistance state. However, in this voltage setting state, if the resistance state of the resistance change type memory element 1 is the high-resistance state, the resistance state of the resistance change type memory element 1 does not change.

As described above, in the resistance change type memory element (a variable resistive element) which is of the bipolar type, the polarity of the voltage (a current or an electric field) is reversed in accordance with the resistance state.

Incidentally, it is needless to say that a threshold value (a voltage value or a current value) required to change the resistance state is present even in the resistance change type memory element which is of the bipolar type.

When the resistance change type memory element 1 is a unipolar type memory element, intensities of voltages (voltage values) applied to the electrodes 13A and 13B, pulse widths of the voltages, or both the voltage values and the pulse widths differ depending on a case that the resistance state of the element is set to the low-resistance state (the program state, writing data “0”) and a case that the resistance state is set to the high-resistance state (the erase state, writing data “1”). In the unipolar resistance change type memory element, voltages applied to terminals have the same polarity. That is, at the time of writing data (changing the resistance state), one of the terminals (the electrodes) of the resistance change type memory element is used as a cathode, and the other is used as an anode.

The resistance change type memory element 1 may be a phase-change element. In the phase-change element, a crystal structure of the resistance change film 14 changes between a crystal phase and an amorphous phase by heat generated due to a supplied current/voltage. As a result, a resistance value of the phase-change element as the memory element changes. The resistance change film 14 of the phase change element is formed by using, e.g., a chalcogen compound such as Ge—Sb—Te, In—Sb—Te, Ag—In—Sb—Te, or Ge—Sn—Te. In the phase-change element as the memory element 1, it is preferable to provide a heater layer between the resistance change film 14 and each of the electrodes 13A and 13B in terms of power consumption.

In the resistance change type memory element using the variable resistive element or the phase-change element, an operation of changing the resistance state of the resistance change type memory element from the high-resistance state to the low-resistance state is called a set operation. An operation of changing the resistance state of the resistance change type memory element from the low-resistance state to the high-resistance state is called a reset operation.

In the bipolar type variable resistive element, since voltages having different polarities are used in the set and reset operations, bi-directionally supplying a current is preferable, as in the MTJ element.

Therefore, for example, in the resistance change type memory according to this embodiment, using the bipolar type variable resistive element as the memory element is preferable.

As described above, the resistance change type memory according to this embodiment can be applied even if the resistance change type memory element is an element other than the MTJ element.

[Other]

According to the resistance change type memory of this embodiment, operation characteristics of the memory can be improved.

In this embodiment, the memory cell array using the memory cells according to this embodiment is not restricted to the foregoing examples, and the connection relationship between the memory cells or the layout of the memory cells may be appropriately changed to form a memory cell array having a circuit configuration and a layout different from those in the foregoing examples.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A resistance change type memory comprising:
a first bit line extending in a first direction;
a first word line extending in a second direction;
a first bipolar transistor which is a first drive type and has a first emitter, a first base, and a first collector;
a second bipolar transistor which is a second drive type different from the first drive type and has a second emitter, a second base, and a second collector; and
a first memory element which has first and second terminals and in which a change in resistance state thereof is associated with data,
wherein the first terminal is connected to the first and second emitters,
the second terminal is connected to the first bit line, and
the first and second bases are connected to the first word line.

2. The memory of claim 1, further comprising:
a second word line which extends in the second direction and is adjacent to the first word line in the first direction;
a third bipolar transistor which is the first drive type and has a third emitter, a third base, and a third collector;
a fourth bipolar transistor which is the second drive type and has a fourth emitter, a fourth base, and a fourth collector; and
a second memory element which has third and fourth terminals and in which a change in resistance states thereof is associated with data,
wherein the third terminal is connected to the third and fourth emitters,
the fourth terminal is connected to the first bit line,
the third and fourth bases are connected to the second word line, and
the third collector is connected to the first collector.

3. The memory of claim 1, further comprising:
a second bit line extending in the first direction;
first and second power supply lines;
a fifth bipolar transistor which is the first drive type and has a fifth emitter, a fifth base, and a fifth collector;
a sixth bipolar transistor which is the second drive type and has a sixth emitter, a sixth base, and a sixth collector; and
a third memory element which has fifth and sixth terminals and in which a change in resistance states thereof is associated with data,
wherein the fifth terminal is connected to the fifth and sixth emitters,
the sixth terminal is connected to the second bit line,
the fifth and sixth bases are connected to the first word line,
the first and fifth collector are connected to the first power supply line, and
the second and the sixth collectors are connected to the second power supply line.

4. The memory of claim 1, wherein, in a write operation with respect to the first memory element,
the first bipolar transistor is turned on and the second bipolar transistor is turned off when the first bit line is set to a first potential and the word line is set to a second potential higher than the first potential, and
the first bipolar transistor is turned off and the second bipolar transistor is turned on when the bit line is set to the second potential and the word line is set to the first potential.

5. The memory of claim 1, wherein, in a read operation with respect to the first memory element,
the bit line is set to a third potential between the second potential and the first potential, and the word line is set to the first potential, and
the first bipolar transistor is turned off, and the second bipolar transistor is turned on.

6. The memory of claim 1, wherein the memory element has a first resistance value and a second resistance value different from the first resistance value,
the memory element exhibits the second resistance value when an output current from the first bipolar transistor flows from the first terminal to the second terminal, and
the memory element exhibits the first resistance value when an output current from the second bipolar transistor flows from the second terminal to the first terminal.

7. A resistance change type memory comprising:
a bit line extending in a first direction above a semiconductor region;
a first bipolar transistor including: a first emitter layer which is of the first conductivity type and provided in the semiconductor region; a first collector layer which is of the first conductivity type and provided in the semiconductor region; and a first base layer which is of a second conductivity type different from the first conductivity type and provided between the first collector layer and the emitter layer;
a second bipolar transistor including: a second emitter layer which is of the second conductivity type and adjacent to the first emitter layer in the semiconductor region; a second collector layer which is of the second conductivity type and provided in the semiconductor region; and a second base layer which is of the first conductivity type and provided between the second collector layer and the second emitter layer in the semiconductor region;
a memory element including: a first terminal which is connected to the first and second emitter layers through a conductor; and a second terminal which is connected to the bit line, resistance states of the memory element being associated with data to be stored; and
a word line which extends in a second direction and is formed of first and second interconnects provided on the first and second base layers.

8. The memory of claim 7, wherein, in a write operation with respect to the memory element,
the first bipolar transistor is turned on and the second bipolar transistor is turned off when the first bit line is set to a first potential and the word line is set to a second potential higher than the first potential, and
the first bipolar transistor is turned off and the second bipolar transistor is turned on when the bit line is set to the second potential and the word line is set to the first potential.

9. The memory of claim 7, wherein, in a read operation with respect to the memory element,
the bit line is set to a third potential between the second potential and the first potential, and the word line is set to the first potential, and
the first bipolar transistor is turned off, and the second bipolar transistor is turned on.

10. The memory of claim 7, wherein the memory element has a first resistance value and a second resistance value different from the first resistance value,
the memory element exhibits the second resistance value when an output current from the first bipolar transistor flows from the first terminal to the second terminal, and
the memory element exhibits the first resistance value when an output current from the second bipolar transistor flows from the second terminal to the first terminal.

11. The memory of claim 7, wherein the semiconductor region is an intrinsic semiconductor region in an SOI substrate.

12. The memory of claim 7, wherein the conductor comprises: a contact plug connected to the first and second emitters in common; and a conductive layer on the contact plug.

13. The memory of claim 7, further comprising:
a silicide layer on the first emitter layer; and
a sidewall insulating film on a side surface of the first interconnect,
wherein the sidewall insulating film covers a boundary portion between the first base layer and the first emitter layer.

14. The memory of claim 7, wherein the first emitter has a portion which overlaps the first base layer.

15. A resistance change type memory comprising:
a bit line extending in a first direction above first and second semiconductor regions;
a first bipolar transistor including: a first collector layer which is a first conductivity type and provided in the first semiconductor region; a first base layer which is a second conductivity type different from the first conductivity type and provided in the first collector layer; and a first emitter layer which is the first conductivity type and provided in the first base layer;
a second bipolar transistor including: a second collector layer which is the second conductivity type and provided in the second semiconductor region; a second base layer which is the first conductivity type and provided in the second collector layer; and a second emitter layer which is the second conductivity type and provided in the second base layer;
a memory element including: a first terminal which is connected to the first and second emitter layers through conductors; and a second terminal connected to the bit line, a resistance state of the memory element being associated with data to be stored; and
a word line which extends in a second direction and is formed of interconnects on the first and second base layers, respectively.

16. The memory of claim 15, wherein, in a write operation with respect to the memory element,
the first bipolar transistor is turned on and the second bipolar transistor is turned off when the first bit line is set to a first potential and the word line is set to a second potential higher than the first potential, and
the first bipolar transistor is turned off and the second bipolar transistor is turned on when the bit line is set to the second potential and the word line is set to the first potential.

17. The memory of claim 15, wherein, in a read operation with respect to the memory element,
the bit line is set to a third potential between the second potential and the first potential, and the word line is set to the first potential, and
the first bipolar transistor is turned off, and the second bipolar transistor is turned on.

18. The memory of claim 15, wherein the memory element has a first resistance value and a second resistance value different from the first resistance value,
the memory element exhibits the second resistance value when an output current from the first bipolar transistor flows from the first terminal to the second terminal, and
the memory element exhibits the first resistance value when an output current from the second bipolar transistor flows from the second terminal to the first terminal.

19. The memory of claim 15, wherein the first terminal of the memory element is provided on a conductive layer above an isolation insulating film between the first and second semiconductor regions, the conductive layer is connected to the first emitter through a first plug, and the conductive layer is connected to the second emitter through a second plug.
